(19) United States
(12) Patent Application Publication
(10) Pub. No.: US 2026/0150657 A1
(43) Pub. Date: May 28, 2026

(54) SEMICONDUCTOR DEVICE INCLUDING GATE CONTACT STRUCTURE, ELECTRONIC APPARATUS INCLUDING THE SEMICONDUCTOR DEVICE, AND METHOD OF MANUFACTURING THE SEMICONDUCTOR DEVICE

(71) Applicant: SAMSUNG ELECTRONICS CO., LTD., Suwon-si (KR)

(72) Inventors: Deokhwan KIM, Suwon-si (KR); Sungmin KIM, Suwon-si (KR); Jaemyeong KIM, Suwon-si (KR); Jeonggeol KIM, Suwon-si (KR); Yongkyung LEE, Suwon-si (KR)

(73) Assignee: SAMSUNG ELECTRONICS CO., LTD., Suwon-si (KR)

(21) Appl. No.: 19/364,554

(22) Filed: Oct. 21, 2025

(30) Foreign Application Priority Data
Nov. 22, 2024 (KR) 10-2024-0168910

(51) Int. Cl. H01L 23/532; H01L 21/768; H01L 23/535

(52) U.S. Cl. CPC H10W 20/4403; H10W 20/0698; H10W 20/20

(57) ABSTRACT

A semiconductor device may include: a channel on a substrate; a first source/drain; a second source/drain spaced apart from the first source/drain in a first direction, wherein the channel is between the first source/drain and the second source/drain in the first direction; a gate insulating layer surrounding the channel; a gate electrode surrounding the channel, wherein the gate insulating layer is between the gate electrode and the channel, and the gate electrode includes a first metal material; and a gate contact structure contacting the gate electrode, the gate contract structure including a second metal material having a lower electrical resistance than an electrical resistance of the first metal material, and wherein the gate contact structure includes a protrusion that protrudes beyond an uppermost end of the gate electrode in a third direction crossing the first direction.

### CROSS-REFERENCE TO RELATED APPLICATION

This application is based on and claims priority under 35 U.S.C. § 119 to Korean Patent Application No. 10-2024-0168910, filed on Nov. 22, 2024, in the Korean Intellectual Property Office, the disclosure of which is incorporated by reference herein in its entirety.

### BACKGROUND

### 1. Field

Some embodiments of the present disclosure relate to a semiconductor device including a gate contact structure, an electronic apparatus including the semiconductor device, and a method of manufacturing the semiconductor device.

### 2. Description of Related Art

In the electronics industry, the demand for smaller, faster electronic devices capable of simultaneously supporting numerous functions continues to increase. Accordingly, the semiconductor industry continues to pursue a trend of manufacturing semiconductor devices that meet the growing demand for low-cost, high-performance, high-density, and low-power integrated circuits (ICs). Up to now, such goals have been largely achieved by reducing the sizes of semiconductor devices and ICs dimensions (e.g., a minimum feature size) to improve the production efficiency and lower the associated costs. However, this expansion has complicated the semiconductor manufacturing processes. Therefore, for continuous advancements in semiconductor devices and ICs, similar advancements in semiconductor manufacturing processes and technologies are required.

As semiconductor devices continue to become smaller, contact features, such as gate contact features and source/drain contact vias, are getting smaller in size and a short circuit risk and capacitance may be increased between different circuit elements such as a gate contact structure, a source/drain contact structure, and a capacitance therebetween. Therefore, there is a need for a semiconductor device including a contact structure to enable a low-power and high-speed operation of a device by reducing the contact resistance.

### SUMMARY

According to embodiments of the present disclosure, a semiconductor device including a gate contact structure capable of reducing a contact resistance, an electronic apparatus including the semiconductor device, and a method of manufacturing the semiconductor device may be provided.

According to embodiments of the present disclosure, a semiconductor device may be provided and include: a channel on a substrate; a first source/drain; a second source/drain spaced apart from the first source/drain in a first direction, wherein the channel is between the first source/drain and the second source/drain in the first direction; a gate insulating layer surrounding the channel; a gate electrode surrounding the channel, wherein the gate insulating layer is between the gate electrode and the channel, and the gate electrode includes a first metal material; and a gate contact structure contacting the gate electrode, the gate contract structure including a second metal material having a lower electrical resistance than an electrical resistance of the first metal material, and wherein the gate contact structure includes a protrusion that protrudes beyond an uppermost end of the gate electrode in a third direction crossing the first direction.

According to embodiments of the present disclosure, a semiconductor device may include: a method of manufacturing a semiconductor device may be provided and include: forming a channel on a substrate; forming a first source/drain at a first end of the channel and a second source/drain at a second end of the channel, wherein the first source/drain and the second source/drain are apart from each other in a first direction; forming a first sacrificial layer structure and a second sacrificial layer structure on the first source/drain and the second source/drain, respectively, wherein each of the first sacrificial layer structure and the second sacrificial layer structure has a first height in a third direction that crosses the first direction; forming a gate insulating layer on the channel; forming a first work function metal layer by using a first metal material on the gate insulating layer such that the first work function metal layer is not folded between the first sacrificial layer structure and the second sacrificial layer structure; forming an organic material layer by applying an organic material on the first work function metal layer; exposing a portion of the first work function metal layer between the first sacrificial layer structure and the second sacrificial layer structure by selectively and partially etching the organic material layer; forming a primary gate electrode structure on the gate insulating layer between the first sacrificial layer structure and the second sacrificial layer structure by etching an exposed portion of the first work function metal layer and removing the organic material layer, the primary gate electrode structure including a bottom portion and two sidewall portion structures, wherein the two sidewall portion structures are spaced apart from each other; folding the primary gate electrode structure between the first sacrificial layer structure and the second sacrificial layer structure by forming a second work function metal layer by using a third metal material on the primary gate electrode structure; obtaining a gate electrode, which includes a folding portion of the primary gate electrode structure, by partially etching the second work function metal layer; and forming a gate contact structure that contacts the gate electrode, the gate contact structure including a second metal material having lower electrical resistance than an electrical resistance of each of the first metal material and the third metal material, the gate contact structure including a protrusion protruding beyond an uppermost end of the gate electrode.

According to embodiments of the present disclosure, electronic apparatus may be provided and include: a substrate; and a plurality of memory cells repeatedly arranged in a first direction and a second direction on the substrate, the second direction crossing the first direction, wherein each of the plurality of memory cells includes: a channel on the substrate; a first source/drain; a second source/drain spaced apart from the first source/drain in the first direction, wherein the channel is between the first source/drain and the second source/drain in the first direction; a gate insulating layer surrounding the channel; a gate electrode surrounding the channel, wherein the gate insulating layer is between the gate electrode and the channel, and the gate electrode includes a first metal material; and a gate contact structure contacting the gate electrode, the gate contract structure including a second metal material having a lower electrical resistance than an electrical resistance of the first metal material, and wherein the gate contact structure includes a protrusion that protrudes beyond an uppermost end of the gate electrode in a third direction crossing the first direction and the second direction.

Additional aspects will be set forth in part in the description which follows and, in part, will be apparent from the description, or may be learned by practice of the example embodiments of the present disclosure.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a schematic plan view illustrating an overall configuration of a semiconductor device according to an embodiment;

FIG. 2 is an on-gate-cut cross-sectional view of the semiconductor device taken along a line A-A′ in FIG. 1;

FIG. 3 is an on-active-cut cross-sectional view of the semiconductor device taken along a line B-B′ in FIG. 1;

FIGS. 4A to 14B are views illustrating a method of manufacturing the semiconductor device of FIGS. 1 to 3, according to an embodiment;

FIG. 15A is a view for explaining a semiconductor device according to an embodiment and shows an on-gate-cut cross-sectional view;

FIG. 15B is a view for explaining a semiconductor device according to an embodiment and shows an on-gate-cut cross-sectional view;

FIGS. 16 to 18 show on-gate-cut cross-sectional views of semiconductor devices according to embodiments, respectively;

FIG. 19 shows an on-active-cut cross-sectional view of each of the semiconductor devices of FIGS. 16 to 18;

FIG. 20 is an equivalent circuit diagram of a memory device according to an embodiment;

FIG. 21 is a schematic circuit diagram of a neural network device according to an embodiment;

FIG. 22 is a schematic block diagram illustrating an example configuration of an electronic apparatus including a neural network device;

FIG. 23 is a schematic conceptual diagram showing a device architecture applicable to an electronic apparatus according to an embodiment;

FIG. 24 is a block diagram of a memory system according to an embodiment; and

FIG. 25 is a block diagram showing a neuromorphic apparatus and an external device connected thereto, according to an embodiment.

### DETAILED DESCRIPTION

Reference will now be made in detail to non-limiting example embodiments of the present disclosure, examples of which are illustrated in the accompanying drawings, wherein like reference numerals refer to like elements throughout. In this regard, embodiments of the present disclosure may have different forms and should not be construed as being limited to the descriptions set forth herein. Accordingly, the example embodiments are merely described below, by referring to the figures, to explain example aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, non-limiting example embodiments of the present disclosure will be described with reference to the accompanying drawings. In the drawings, like reference numerals refer to like elements, and the sizes of elements may be exaggerated for clarity of illustration. The example embodiments described herein are for illustrative purposes only, and various modifications may be made therein without departing from the spirit and scope of the present disclosure.

In the following description, when an element is referred to as being “above” or “on” another element, it may be directly on an upper, lower, left, or right side of the other element while making contact with the other element or may be above an upper, lower, left, or right side of the other element without making contact with the other element. The terms of a singular form may include plural forms unless otherwise mentioned. It will be further understood that the terms “includes” (or “comprises”) and/or “including” (or “comprising”) used herein specify the presence of stated features or elements, but do not preclude the presence or addition of one or more other features or elements.

An element referred to with a definite article or a demonstrative pronoun may be construed as the element or the elements even though it has a singular form. Operations of a method may be performed in an appropriate order unless explicitly described in terms of order or described to the contrary, and are not limited to the stated order thereof.

Also, terms such as “unit” or “module” used herein may be used to denote a unit that has at least one function or operation and is implemented with hardware, software, or a combination of hardware and software.

The term “surround” (and “surrounding”) may include “partially surround” (and “partially surrounding”) in at least one direction (e.g., a horizontal direction and/or a vertical direction).

Furthermore, line connections or connection members between elements depicted in the drawings represent functional connections and/or physical or circuit connections by way of example, and in actual applications, they may be replaced or embodied with various additional functional connections, physical connections, or circuit connections. Various regions illustrated in the drawings are schematic, and may not represent the region shapes of actual devices, and do not limit the scope of the present disclosure. In addition, the sizes and relative sizes of layers and regions may be exaggerated for clarity in the drawings.

For brevity, existing elements, structures, or layers of semiconductor devices and materials forming them may not be described in detail in the present specification. For example, descriptions of certain insulating layers or structures of semiconductor devices and materials forming them may be omitted when they are not relevant to novel features of the present disclosure. In addition, materials forming well-known structural elements of semiconductor devices may be omitted when they are not relevant to novel features of the present disclosure. The term “insulation” herein means electrical insulation or separation between structures, layers, components, or regions of a device or structure.

All examples and terms are used herein just to describe example technical aspects of the present disclosure, and should not be considered for purposes of limitation

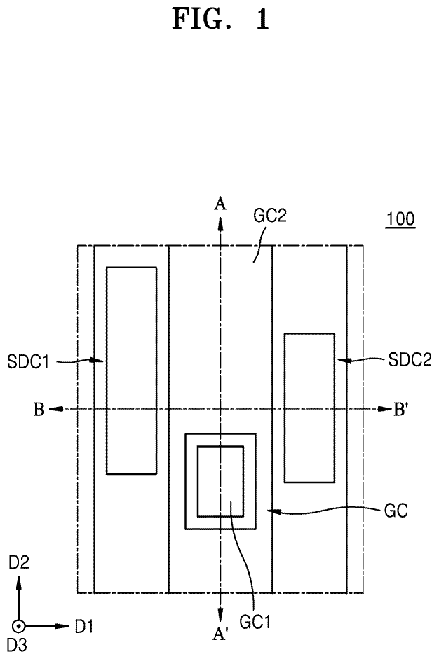

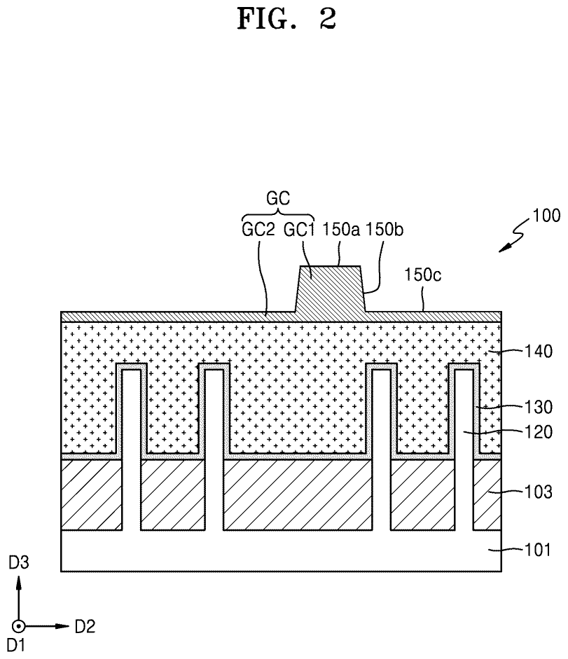

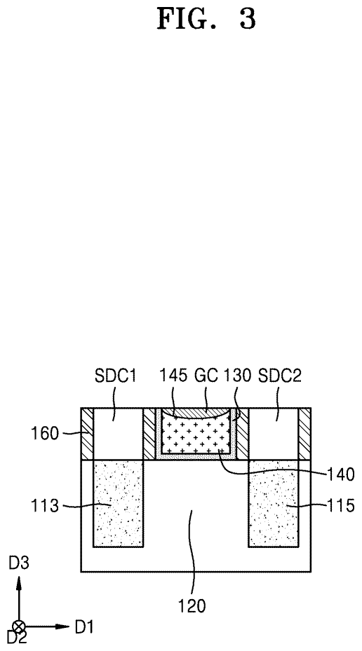

FIGS. 1 to 3 are views for explaining a semiconductor device 100 according to an embodiment. FIG. 1 is a schematic plan view illustrating an overall configuration of the semiconductor device 100 according to an embodiment. FIG. 2 is an on-gate-cut cross-sectional view of the semiconductor device 100 taken along a line A-A′ in FIG. 1. FIG. 3 is an on-active-cut cross-sectional view of the semiconductor device 100 taken along a line B-B′ in FIG. 1. In FIGS. 2 and 3 and other drawings below, some components are omitted for convenience of explanation.

Referring to FIGS. 1 to 3, the semiconductor device 100 according to an embodiment may include a channel 120 provided on a substrate 101, a gate insulating layer 130 provided to surround the channel 120, a gate electrode 140 provided to surround the channel 120 with the gate insulating layer 130 therebetween, and a gate contact structure GC formed in contact on the gate electrode 140. The semiconductor device 100 according to an embodiment may further include a first source/drain 113 and a second source/drain 115, which are apart from each other in a first direction D1 with the channel 120 therebetween, and first source/drain contact structure SDC1 and the second source/drain contact structure SDC2 formed in contact with the first source/drain 113 and the second source/drain 115, respectively.

As illustrated in FIG. 1, the first source/drain contact structure SDC1 and the second source/drain contact structure SDC2 may be apart from each other in the first direction D1, and the gate contact structure GC may be positioned between the first source/drain contact structure SDC1 and the second source/drain contact structure SDC2.

As illustrated in FIG. 2, the gate contact structure GC may include a protrusion GC1 that protrudes beyond an uppermost end of the gate electrode 140 in a third direction D3 that is perpendicular to the first direction D1, and may further include a flat portion GC2 that is lower than the protrusion GC1 in the third direction D3. A first surface of the flat portion GC2 may contact the gate electrode 140, and the protrusion GC1 may protrude in the third direction D3 with respect to (e.g., from) a second surface of the flat portion GC2 that is opposite to the first surface of the flat portion GC2. In an embodiment described below, the gate contact structure GC may have only the protrusion GC1. In FIG. 2, the protrusion GC1 may include an upper end 150a and a side surface 150b having a slope, and the flat portion GC2 may have an upper surface 150c. The upper surface 150c of the flat portion GC2 may be the second surface of the flat portion GC2 that is opposite to the first surface of the gate contact structure GC that contacts the gate electrode 140.

The gate contact structure GC may include a metal material having a lower resistance (e.g., lower electrical resistance) than a resistance (e.g., electrical resistance) of the metal material forming the gate electrode 140. For example, the gate contact structure GC may include at least one from among a metal, a metal nitride, a metal carbide, and a combination thereof. For example, the metal may include at least one from among Ti, W, Ru, Nb, Mo, Hf, Ni, Co, Pt, Yb, Tb, Dy, Er, Al, La, Ta, and Pd. The metal nitride may include, for example, titanium nitride (TiN) or tantalum nitride (TaN). The metal carbide may include, for example, TiAlC, TaAlC, TiSiC, or TaSiC. The gate contact structure GC may include a metal material selected from various metal materials described above, but a metal material having lower resistance (e.g., lower electrical resistance) than a resistance (e.g., electrical resistance) of the metal material forming the gate electrode 140 may be selected. For example, the gate contact structure GC may include at least one from among tungsten (W) and cobalt (Co).

As shown in FIG. 3, the first source/drain 113 and the second source/drain 115 may be positioned to be apart from each other below the first source/drain contact structure SDC1 and the second source/drain contact structure SDC2, respectively, in the third direction D3. In addition, the channel 120 may be positioned between the first source/drain 113 and the second source/drain 115. As shown in FIG. 3, the first source/drain 113 may be formed on one side of the channel 120 in the first direction D1, and the second source/drain 115 may be formed on the other side of the channel 120 in the first direction D1. In this case, the first source/drain 113 and the first source/drain contact structure SDC1 may constitute a first source/drain structure, and the second source/drain 115 and the second source/drain contact structure SDC2 may constitute a second source/drain structure.

The first source/drain contact structure SDC1 may connect the first source/drain 113 to one wiring line, and the second source/drain contact structure SDC2 may connect the second source/drain 115 to another wiring line. One end of the first source/drain contact structure SDC1 may be in contact with the first source/drain 113, and the other end of the first source/drain contact structure SDC1 may be in contact with a wiring line. One end of the second source/drain contact structure SDC2 may be in contact with the second source/drain 115, and the other end of the second source/drain contact structure SDC2 may be in contact with a wiring line. The first source/drain contact structure SDC1 and the second source/drain contact structure SDC2 may include a conductive material.

The first source/drain contact structure SDC1 and the second source/drain contact structure SDC2 may each include a conductive pattern and a barrier pattern surrounding the conductive pattern. For example, the conductive pattern may include at least one metal from among aluminum, copper, tungsten, molybdenum, and cobalt. The barrier pattern may cover sidewalls and a bottom surface of the conductive pattern. The barrier pattern may include a metal layer/metal nitride layer. The metal layer may include at least one from among titanium, tantalum, tungsten, nickel, cobalt, and platinum. The metal nitride layer may include at least one from among a titanium nitride (TiN) layer, a tantalum nitride (TaN) layer, a tungsten nitride (WN) layer, a nickel nitride (NiN) layer, a cobalt nitride (CoN) layer, and a platinum nitride (PtN) layer.

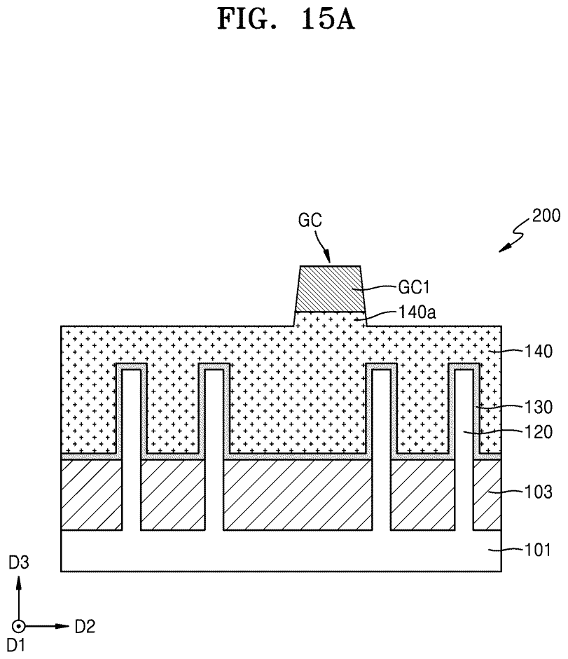

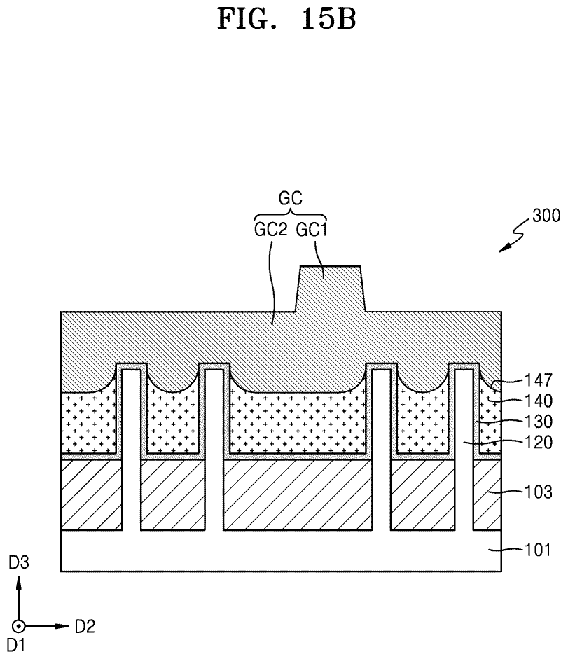

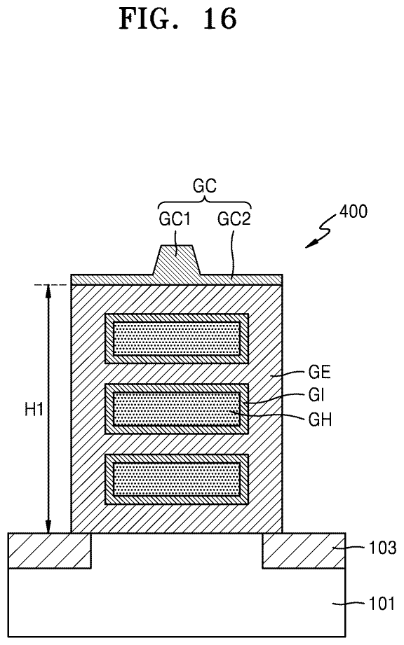

The first direction D1 may be a channel length direction in which current flows between the first source/drain 113 and the second source/drain 115 connected to each other through the channel 120 illustrated in FIGS. 2 and 3. A second direction D2 intersecting the first direction D1 may be a direction along a width of the channel 120. The third direction D3 may be perpendicular to the first direction D1 and the second direction D2, and may be a direction along a height of the channel 120 when the channel 120 is a fin channel as illustrated in FIG. 2. As shown in FIGS. 16 to 19 described below, when a channel CH is a gate all around (GAA) channel, the third direction D3 may be a direction in which nanosheet-shaped channels CH are stacked.

The gate contact structure GC, the first source/drain contact structure SDC1, and the second source/drain contact structure SDC2 may be provided in various layouts. For example, in the example shown in FIG. 1, the first source/drain contact structure SDC1, the second source/drain contact structure SDC2, and the protrusion GC1 of the gate contact structure GC may be provided at different levels in the second direction D2, such that one from among the first source/drain contact structure SDC1 and the second source/drain contact structure SDC2 may be provided at a level between the gate contact structure GC and the other from among the first source/drain contact structure SDC1 and the second source/drain contact structure SDC2 in the second direction D2. This is only an example, and the first source/drain contact structure SDC1, the second source/drain contact structure SDC2, and the gate contact structure GC may be formed in various layouts. Hereinafter, the gate contact structure GC, the gate electrode 140, and configurations related thereto will be mainly described.

Referring to FIGS. 2 and 3, the substrate 101 on which the semiconductor device 100 is manufactured may be an insulating substrate or a semiconductor substrate. An insulating layer may be further provided on the semiconductor substrate. For example, the substrate 101 may be a semiconductor substrate including silicon (Si), such as single crystal silicon, polycrystalline silicon, or amorphous silicon. However, the material of the substrate 101 is not limited to silicon. For example, the substrate 101 may be a semiconductor substrate including germanium (Ge), silicon germanium (SiGe), silicon carbide (SiC), or a III-V group semiconductor material, such as gallium arsenide (GaAs), indium arsenide (InAs), or indium phosphide (InP).

For example, the substrate 101 may be based on a silicon bulk substrate, or may be based on a silicon on insulator (SOI) substrate. In addition, the substrate 101 is not limited to the silicon bulk or SOI substrate, and may be a substrate based on an epitaxial wafer, a polished wafer, an annealed wafer, etc. According to some embodiments of the present disclosure, the substrate 101 may include conductive regions doped with impurities, or various structures doped with impurities. In addition, the substrate 101 may be configured as a P-type substrate or an N-type substrate depending on the type of impurity ion being doped.

A device isolation layer 103 may be formed in the substrate 101 to separate the channels 120 from each other. The device isolation layer 103 may include any one from among an oxide, a nitride, and an oxynitride. As illustrated in FIG. 2, when the channel 120 is a fin channel extending in the first direction D1, the device isolation layer 103 may separate fins from each other in the second direction D2. The device isolation layer 103 may be arranged in a buried structure inside the substrate 101 and may include an insulating material. For example, the device isolation layer 103 may be formed by forming a trench in the substrate 101 and filling the trench with an insulating material, such as an oxide. As illustrated in FIG. 2, when the channel 120 is a fin channel, the device isolation layer 103 may be arranged to separate fins from each other in the first direction D1 and the second direction D2.

The channel 120 may be formed to have a fin channel that extends from the substrate 101 and protrudes in the third direction D3 from the upper surface of the device isolation layer 103. The fin channel may extend, for example, in the first direction D1.

The channel 120 may be formed as a substrate base or implemented as a separate material layer. For example, when the channel 120 is formed as a substrate base, the channel 120 may include a semiconductor material, such as silicon (Si), germanium (Ge), silicon germanium (SiGe), silicon carbide (SiC), or a III-V group semiconductor material such as, for example, gallium arsenide (GaAs), indium arsenide (InAs), or indium phosphide (InP). In addition, when the channel 120 is not formed as a substrate base but is implemented as a separate material layer, the channel 120 may include Si, Ge, SiGe, SiC, a III-V group semiconductor material, an oxide semiconductor, a nitride semiconductor, an oxynitride semiconductor, a two-dimensional (2D) material, quantum dots, and/or an organic semiconductor. For example, the channel 120 may include a material from among oxide semiconductors such as, for example, InGaZnO, ZnO, ZrInZnO, InZnO, ZnO, InGaZnO₄, ZnInO, ZnSnO, In₂O₃, Ga₂O₃, HfInZnO, GaInZnO, HfO₂, SnO₂, WO₃, TiO₂, Ta₂O₅, In₂O₃SnO₂, MgZnO, ZnSnO₃, ZnSnO₄, CdZnO, CuAlO₂, CuGaO₂, Nb₂O₅, TiSrO₃, zinc indium oxide (ZIO), indium gallium oxide (IGO), and combinations thereof. For example, the channel 120 may include a two-dimensional (2D) material such as, for example, transition metal dichalcogenide (TMD) or graphene. The TMD may include a compound of a transition metal and a chalcogen element. For example, the TMD may include MoS₂, MoSe₂, MoTe₂, WS₂, WSe₂, WTe₂, ZrS₂, ZrSe₂, HfS₂, HfSe₂, NbSe₂, ReSe₂, etc. The quantum dots may include colloidal quantum dots (colloidal QDs) or a nanocrystal structure.

In this way, the channel 120 may be, for example, a fin channel formed by extending in the third direction D3 perpendicular to the substrate 101. Hereinafter, a fin field effect transistor (FinFET) structure will be described as an example, but the descriptions provided below may also apply to various structures, such as a GAA structure.

The first source/drain 113 and the second source/drain 115 may be high-concentration doped regions. For example, when the channel 120 is a fin channel, the first source/drain 113 and the second source/drain 115 may be formed by heavily doped areas on opposite sides of the fins, or may be formed through epi growth after removing upper portions of the fins.

The gate insulating layer 130 may be provided between the channel 120 and the gate electrode 140. The gate insulating layer 130 may include silicon oxide, silicon oxynitride, and/or a dielectric material. For example, the gate insulating layer 130 may include a silicon oxide layer directly covering the surface of the channel 120 and a high-k dielectric material layer on the silicon oxide layer. In other words, the gate insulating layer 130 may include a multi-layer including a silicon oxide layer and a high-k dielectric material layer. The silicon oxide layer may include, for example, SiO₂ or SiON. The high-k dielectric material layer may include a dielectric material having a higher dielectric constant than a dielectric constant of silicon oxide. The high-k dielectric material layer may include a hafnium (Hf)-based or zirconium (Zr)-based material or may also include another material. That is, the high-k dielectric material layer may include at least one from among hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate.

As another example, the gate insulating layer 130 may be formed to have ferroelectric properties. For example, the gate insulating layer 130 may include a ferroelectric material layer having ferroelectric properties and a paraelectric material layer having paraelectric properties. The ferroelectric material layer may include, for example, at least one from among hafnium oxide, hafnium zirconium oxide, barium strontium titanium oxide, barium titanium oxide, and lead zirconium titanium oxide. In this case, as an example, the hafnium zirconium oxide may be a material in which zirconium (Zr) is doped into hafnium oxide. As another example, the hafnium zirconium oxide may be a compound of hafnium (Hf), zirconium (Zr), and oxygen (O).

The ferroelectric material layer may further include a doped dopant. For example, the dopant may include at least one from among aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). Depending on which ferroelectric material the ferroelectric material layer includes, the type of dopant included in the ferroelectric material layer may vary.

When the ferroelectric material layer includes hafnium oxide, the dopant included in the ferroelectric material layer may include at least one from among, for example, gadolinium (Gd), silicon (Si), zirconium (Zr), aluminum (Al), and yttrium (Y). When the dopant is aluminum (Al), the ferroelectric material layer may include about 3 atomic % (at %) to about 8 at % of aluminum. In this case, the ratio of the dopant may be the ratio of aluminum to the sum of hafnium and aluminum. When the dopant is silicon (Si), the ferroelectric material layer may include about 2 at % to about 10 at % of silicon. When the dopant is yttrium (Y), the ferroelectric material layer may include about 2 at % to about 10 of yttrium. When the dopant is gadolinium (Gd), the ferroelectric material layer may include about 1 at % to about 7 at % of gadolinium. When the dopant is zirconium (Zr), the ferroelectric material layer may include about 50 at % to about 80 at % of zirconium.

The paraelectric material layer may have paraelectric properties. The paraelectric material layer may include, for example, at least one from among silicon oxide and a metal oxide having a high dielectric constant. The metal oxide of the paraelectric material layer may include, but is not limited to, at least one from among hafnium oxide, zirconium oxide, and aluminum oxide.

The ferroelectric material layer and the paraelectric material layer may include the same material as each other. The ferroelectric material layer may have ferroelectric properties, but the paraelectric material layer may not have ferroelectric properties. For example, when the ferroelectric material layer and the paraelectric material layer include hafnium oxide, the crystal structure of the hafnium oxide in the ferroelectric material layer may be different from the crystal structure of the hafnium oxide in the paraelectric material layer.

The ferroelectric material layer may have a thickness having ferroelectric properties. The thickness of the ferroelectric material layer may be, for example, about 0.5 nm to about 10 nm or about 1 nm to about 2 nm, but is not limited thereto. Because the critical thickness exhibiting ferroelectric properties may vary for each ferroelectric material, the thickness of the ferroelectric material layer may vary depending on the ferroelectric material.

As an example, the gate insulating layer 130 may include one ferroelectric material layer. As another example, the gate insulating layer 130 may include a plurality of ferroelectric material layers that are apart from each other. The gate insulating layer 130 may have a stacked layer structure in which a plurality of ferroelectric material layers and a plurality of paraelectric material layers are alternately stacked.

The gate electrode 140 may include at least one from among conductive material among metal, metal nitride, metal carbide, polysilicon, and combinations thereof. For example, the metal may include at least one from among Ti, W, Ru, Nb, Mo, Hf, Ni, Co, Pt, Yb, Tb, Dy, Er, Al, La, Ta, and Pd. The metal nitride may include, for example, titanium nitride (TiN) or tantalum nitride (TaN). The metal carbide may include, for example, TiAlC, TaAlC, TiSiC, or TaSiC. In an embodiment, the gate electrode 140 may include a single layer or a multi-layer including two or more layers. For example, the gate electrode 140 may include a TiN layer, a stacked structure of TiAlC/TiN layers, a stacked structure of TiAlC/TiN/W layers, a stacked structure of TiN/TaN/TiAlC/TiN/W layers, or a stacked structure of TiN/TaN/TiN/TiAlC/TiN/W layers, but is not limited thereto.

The gate insulating layer 130 and the gate electrode 140 may constitute a gate structure. The gate structure may further include a spacer 160. For example, the gate structure may include the gate insulating layer 130, the gate electrode 140, and the spacer 160. For example, when the channel 120 is a fin channel, the spacer 160 may be arranged between the gate electrode 140 and the first source/drain contact structure SDC1 and between the gate electrode 140 and the second source/drain contact structure SDC2. Referring to FIG. 3, for example, when the first source/drain contact structure SDC1, the gate electrode 140, and the second source/drain contact structure SDC2 are arranged in the first direction D1, parasitic capacitance may occur between the first source/drain contact structure SDC1 and the gate electrode 140 and between the gate electrode 140 and the second source/drain contact structure SDC2. The spacer 160 may reduce the parasitic capacitance. The spacer 160 may include, for example, at least one from among SiCN, SiCON, and SiN. The spacer 160 may include, for example, a multi-layer including at least two from among SiCN, SiCON, and SiN.

As illustrated in FIG. 3, at least a portion of the upper surface of the gate electrode 140 with which the gate contact structure GC is in contact may have a curved surface 145. The shape of the curved surface 145 may be due to the formation of the gate electrode 140 by performing a work function metal layer stack process twice according to a semiconductor device manufacturing method according to an embodiment.

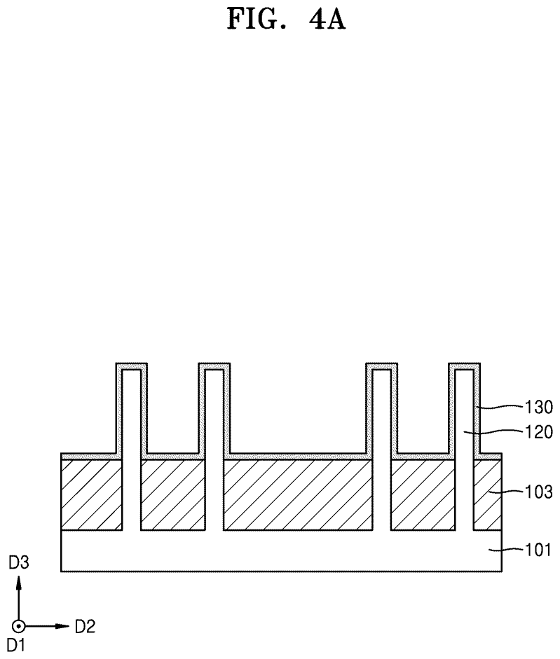

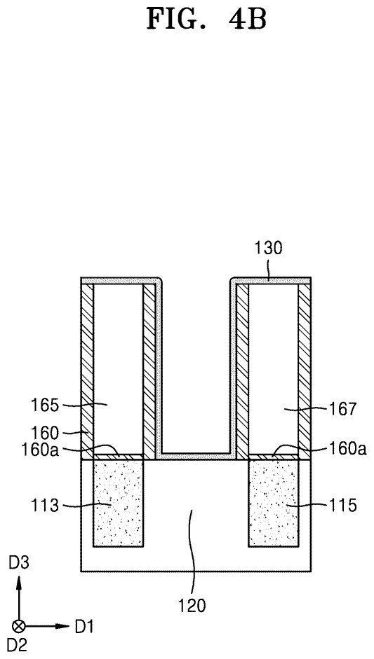

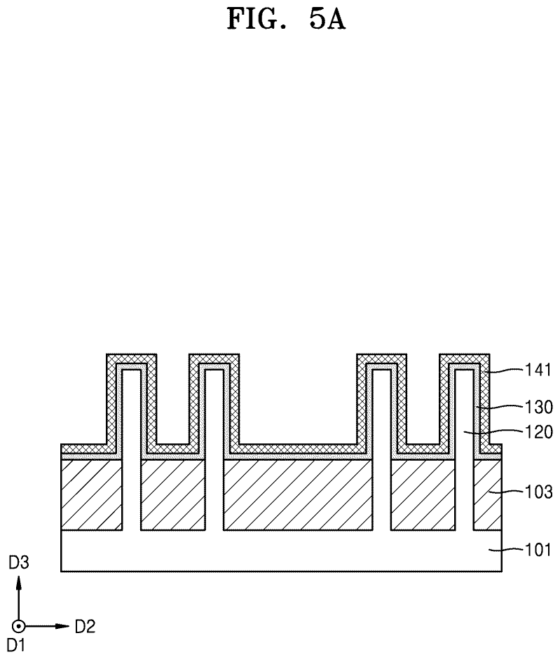

FIGS. 4A to 14B are views illustrating a method of manufacturing the semiconductor device 100 described with reference to FIGS. 1 to 3, according to an embodiment. FIGS. 4A, 5A, 6A, 7A, 8A, 9A, 10A, 11A, 12A, 13A, and 14A show on-gate-cut cross-sectional views, and FIGS. 4B, 5B, 6B, 7B, 8B, 9B, 10B, 11B, 12B, 13B, and 14B show on-active-cut cross-sectional views. In FIGS. 4A to 14B, components using the same reference numerals as those in FIGS. 1 to 3 correspond to substantially the same components as those in FIGS. 1 to 3, and therefore, repeated descriptions thereof may be omitted herein. Hereinafter, a structure in which a channel 120 is formed as a fin channel extending in a third direction D3 perpendicular to a substrate 101 is described, but the descriptions provided below may also apply to various structures, such as a GAA structure.

Referring to FIGS. 4A and 4B, the channel 120 may be formed on the substrate 101, and a first source/drain 113 and a second source/drain 115 may be formed at opposite ends of the channel 120 and apart from each other in a first direction D1. A first sacrificial layer structure 165 and a second sacrificial layer structure 167 each having a first height in the third direction D3 may be formed on the first source/drain 113 and the second source/drain 115, respectively. In addition, a gate insulating layer 130 may be formed to cover the channel 120.

An etch stop layer 160a may be formed on the first source/drain 113 and the second source/drain 115, and the first sacrificial layer structure 165 and the second sacrificial layer structure 167 may be formed on the etch stop layer 160a to the first height. The first sacrificial layer structure 165 and the second sacrificial layer structure 167 may be formed on the first source/drain 113 and the second source/drain 115, respectively, and may have a structure without the etch stop layer 160a. A spacer 160 may be further formed on opposite sides of each of the first sacrificial layer structure 165 and the second sacrificial layer structure 167.

The etch stop layer 160a may be a layer for protecting the first source/drain 113 and the second source/drain 115 during a partial etching process for forming a gate electrode structure GC. The etch stop layer 160a may include the same material as the spacer 160 or a different material from the spacer 160. The first sacrificial layer structure 165 and the second sacrificial layer structure 167 may include, for example, an oxide. The spacer 160 may include an insulating material such as, for example, silicon oxide. For example, after a structure including the etch stop layer 160a and the spacer 160 is formed, a sacrificial layer material may be filled on the etch stop layer 160a to form the first sacrificial layer structure 165 and the second sacrificial layer structure 167. As another example, the etch stop layer 160a may be formed, the first sacrificial layer structure 165 and the second sacrificial layer structure 167 may be formed on the etch stop layer 160a, and the spacer 160 may be formed to cover the sidewalls of the first sacrificial layer structure 165 and the second sacrificial layer structure 167.

A gate insulating layer 130 may be formed on the channel 120. The gate insulating layer 130 may be formed on the channel 120 exposed between the first sacrificial layer structure 165 and the second sacrificial layer structure 167, as illustrated in FIG. 4B, and may be formed to cover the first sacrificial layer structure 165 and the second sacrificial layer structure 167. When the spacer 160 is formed on both sidewalls of each of the first sacrificial layer structure 165 and the second sacrificial layer structure 167, the gate insulating layer 130 may be formed on the channel 120 and may be formed to cover the side surface of the spacer 160 and the upper ends of the first sacrificial layer structure 165 and the second sacrificial layer structure 167.

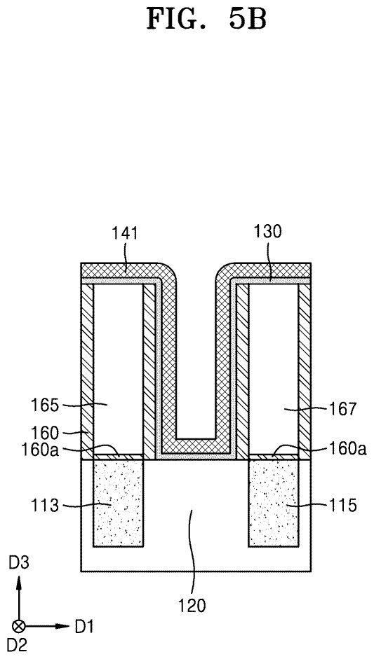

Referring to FIGS. 5A and 5B, a first work function metal layer 141 may be formed on the gate insulating layer 130 by using a first metal material. The first work function metal layer 141 may include, for example, pTiN. In addition, the first work function metal layer 141 may include various metals that may constitute the gate electrode 140. The first work function metal layer 141 may be formed so as not to be folded between the first sacrificial layer structure 165 and the second sacrificial layer structure 167, as illustrated in FIG. 5B. The first work function metal layer 141 may constitute a portion of the gate electrode 140.

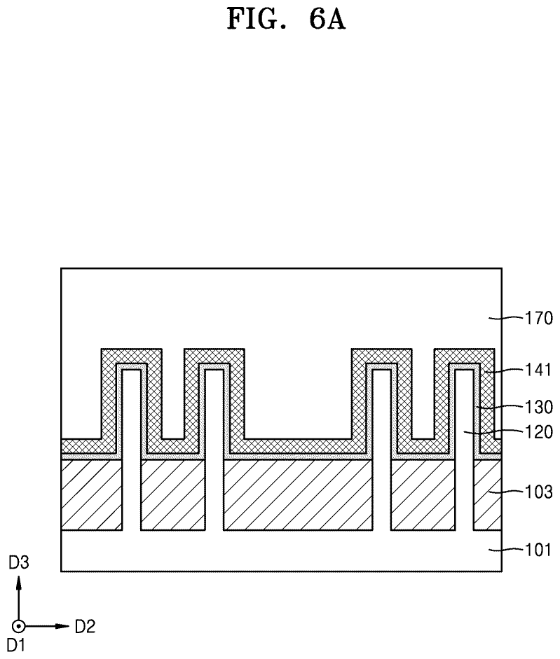

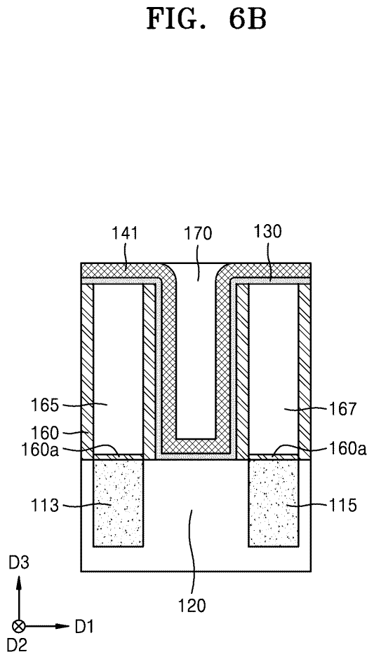

Referring to FIGS. 6A and 6B, an organic material may be applied on the first work function metal layer 141 to form an organic material layer 170. In this case, the organic material layer 170 may be formed to cover at least a portion of the first work function metal layer 141 between the first sacrificial layer structure 165 and the second sacrificial layer structure 167, as illustrated in FIG. 6B. The organic material layer 170 may include an organic material that may be used in a masking process, such as a carbon-based organic material.

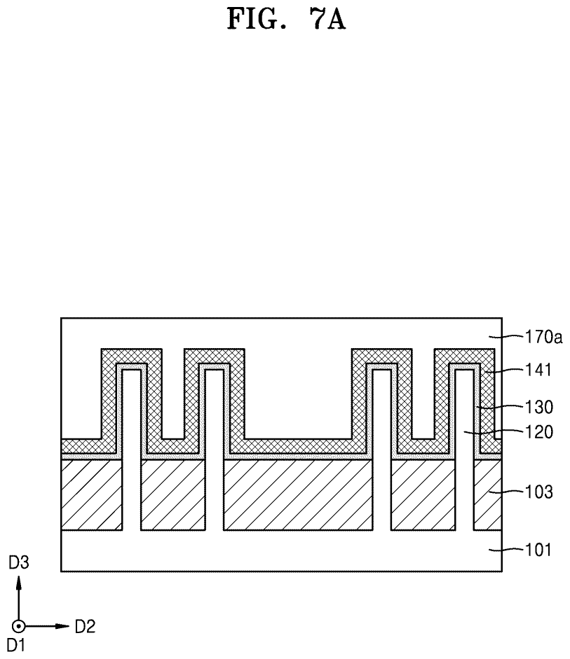

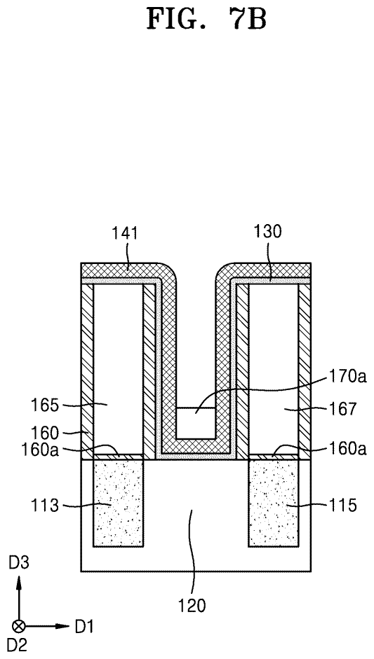

Next, referring to FIGS. 7A and 7B, the organic material layer 170 may be selectively and partially etched. By selectively and partially etching the organic material layer 170, at least a portion of the first work function metal layer 141 may be exposed. In FIGS. 7A and 7B, a remaining portion 170a of the organic material layer 170 may remain by selective partial etching.

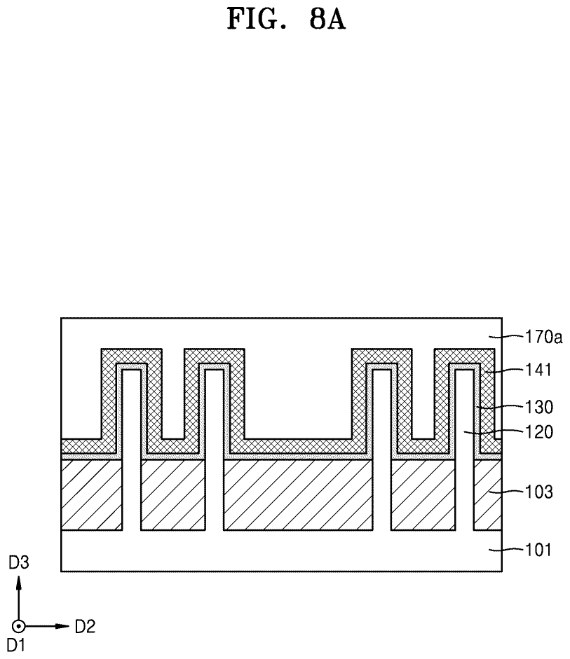

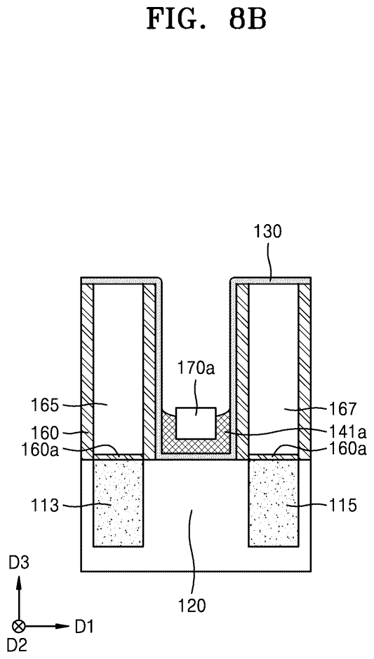

Next, referring to FIGS. 8A and 8B, a portion of the first work function metal layer 141 exposed from the upper end of the remaining portion 170a of the organic material layer 170 may be etched. Thus, a primary gate electrode structure 141a including a bottom portion and two spaced sidewall portion structures may be formed on the gate insulating layer 130 between the first sacrificial layer structure 165 and the second sacrificial layer structure 167.

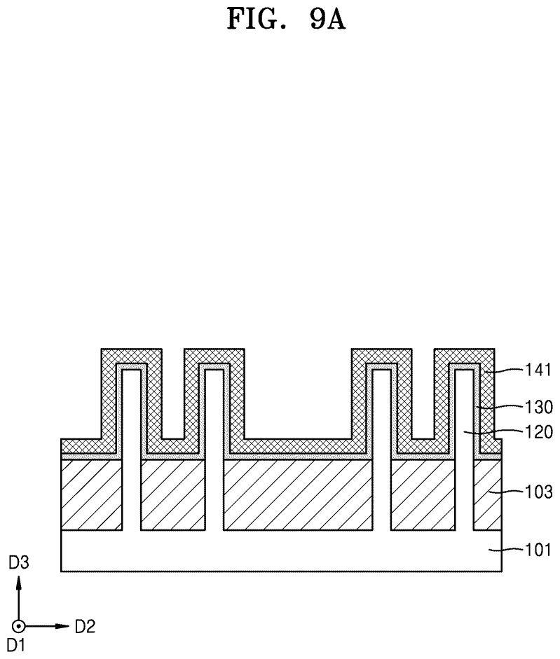

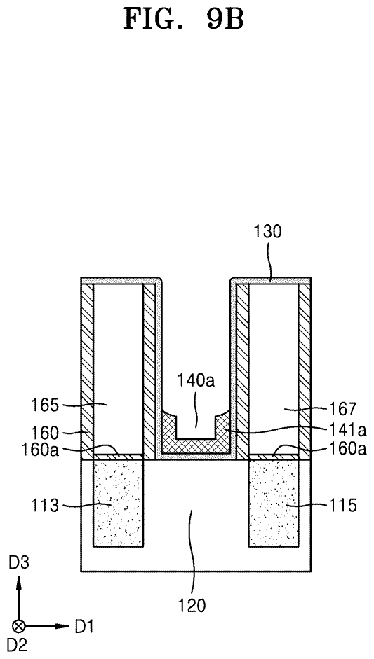

Next, referring to FIGS. 9A and 9B, the remaining portion 170a of the organic material layer 170 may be removed. In FIG. 9B, a region (folding portion 140a) where folding occurs with respect to the primary gate electrode structure 141a to form the gate electrode 140 in the following process.

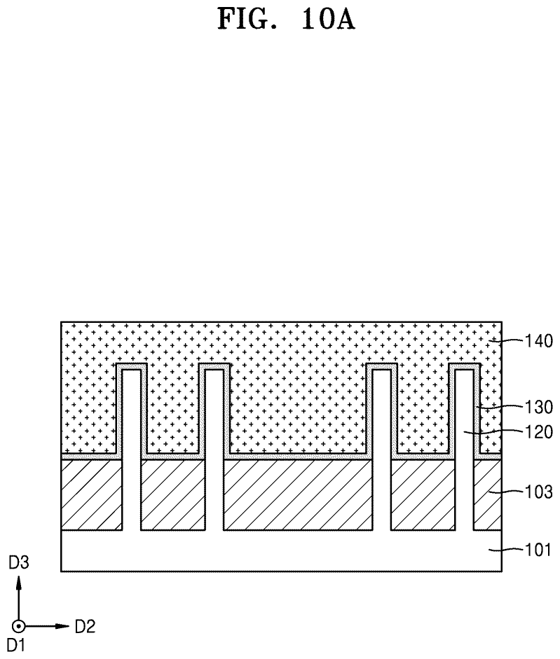

Next, referring to FIGS. 10A and 10B, a second work function metal layer 143 may be formed on the primary gate electrode structure 141a by using a third metal material, and thus, the primary gate electrode structure 141a may be folded due to a narrow width of the primary gate electrode structure 141a during forming the second work function metal layer 143. The first metal material and the third metal material may be the same metal material as each other, and in this case, the second work function metal layer 143 may not be distinguished (or separated) as a layer from the first work function metal layer 141. As another example, the first metal material and the third metal material may be metal materials having at least one different component with respect to each other, and the second work function metal layer 143 may or may not be distinguished as a layer from the first work function metal layer 141. As another example, the first metal material and the third metal material may be metal materials having at least one different component with respect to each other, and the second work function metal layer 143 may be distinguished as a layer from the first work function metal layer 141.

For example, the gate electrode 140 may include the first work function metal layer 141 and the second work function metal layer 143. The gate electrode 140 may have a structure in which the primary gate electrode structure 141a formed of the first work function metal layer 141 on the gate insulating layer 130 and the region (the folding portion 140a) where folding occurs with respect to the primary gate electrode structure 141a are filled as the second work function metal layer 143 between the first sacrificial layer structure 165 and the second sacrificial layer structure 167. In addition, the gate electrode 140 may be formed such that the second work function metal layer 143 is not or is distinguished as a layer from the first work function metal layer 141. FIGS. 10A and 10B show an example in which the second work function metal layer 143 is not distinguished as a layer from the first work function metal layer 141.

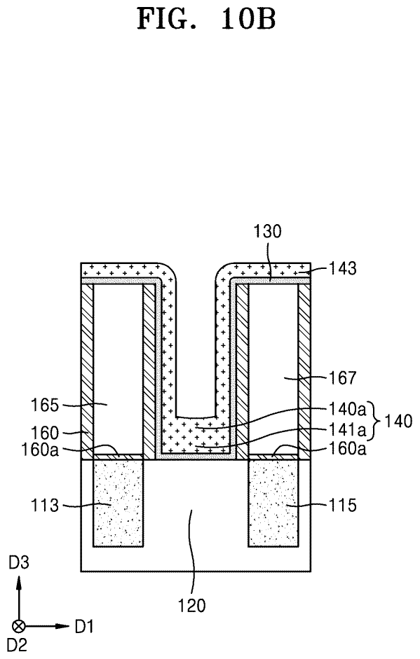

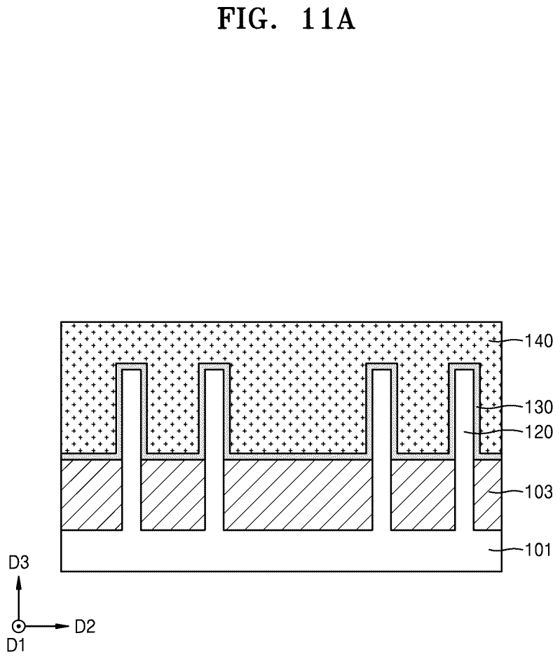

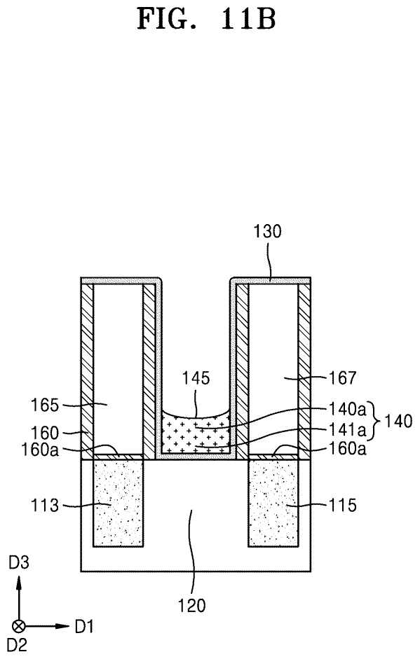

Next, referring to FIGS. 11A and 11B, the second work function metal layer 143 may be partially etched to obtain the gate electrode 140 including the folding portion 140a of the primary gate electrode structure 141a. In this case, the second work function metal layer 143 may be partially etched to a thickness equivalent to the thickness of the third metal material applied in FIGS. 10A and 10B. Accordingly, the maximum thickness of the gate electrode 140 may be substantially the same as the thickness of the primary gate electrode structure 141a, and only the folding portion 140a of the primary gate electrode structure 141a may be filled with the third metal material. As another example, the second work function metal layer 143 may be partially etched to a thickness smaller than the thickness of the third metal material applied in FIGS. 10A and 10B, and the maximum thickness of the gate electrode 140 may be larger than the thickness of the primary gate electrode structure 141a.

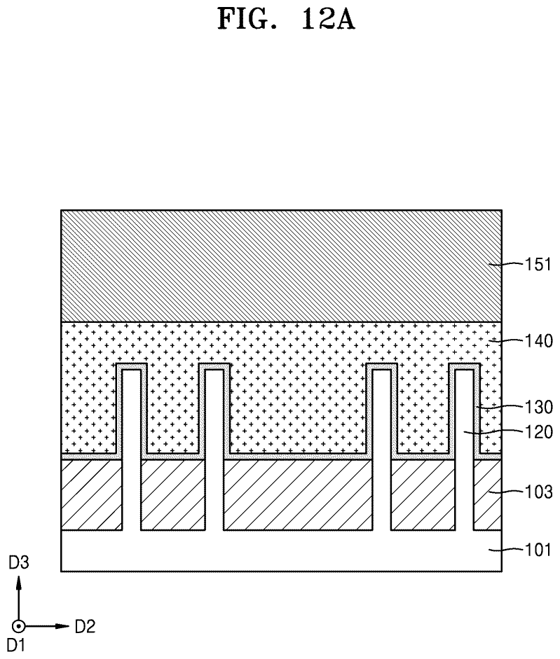

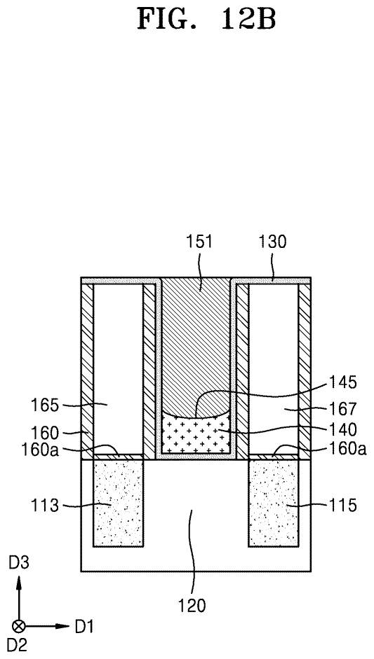

Next, referring to FIGS. 12a and 12b, a second metal material to be used as a gate contact metal may be applied on the gate electrode 140 to contact the gate electrode 140, thereby forming a metal material layer 151. The second metal material may be a metal material having a low resistance (e.g., a low electrical resistance) compared to a resistance (e.g., an electrical resistance) of the first and third metal materials constituting the gate electrode 140. For example, the second metal material may include at least one from among a metal, a metal nitride, a metal carbide, and a combination thereof. For example, the metal may include at least one from namong Ti, W, Ru, Nb, Mo, Hf, Ni, Co, Pt, Yb, Tb, Dy, Er, Al, La, Ta, and Pd. The metal nitride may include, for example, titanium nitride (TiN) or tantalum nitride (TaN). The metal carbide may include, for example, TiAlC, TaAlC, TiSiC, or TaSiC. The second metal material may be selected from various metal materials described above, but a metal material having lower resistance (e.g., a lower electrical resistance) than a resistance (e.g., electrical resistance) of the first and third metal materials may be selected. For example, the metal material layer 151 may include at least one from among tungsten (W) and cobalt (Co).

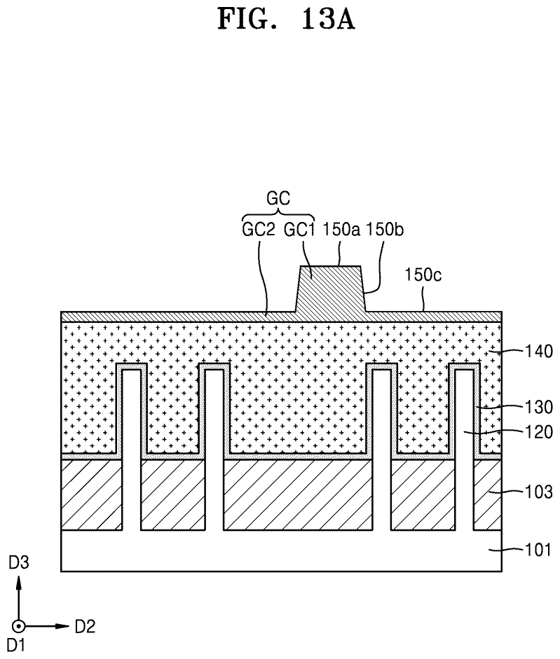

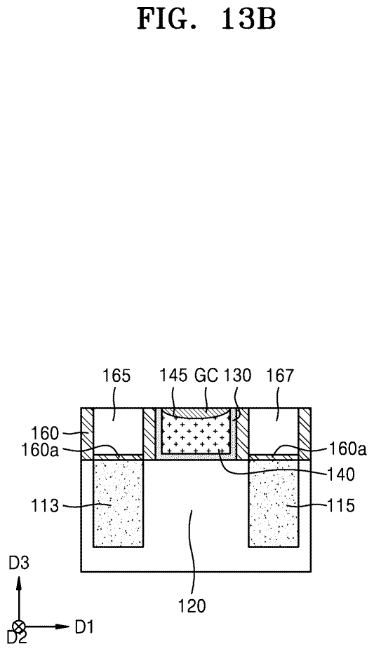

Next, referring to FIGS. 13A and 13B, the metal material layer 151 may be partially etched to form a gate contact structure GC. In this case, the gate contact structure GC may be formed to have a protrusion GC1 that protrudes beyond the uppermost end of the gate electrode 140. For example, as illustrated in FIG. 13A, the gate contact structure GC may include a flat portion GC2 that has a first surface contacting the gate electrode 140, and the protrusion GC1 may be formed to protrude in a third direction with respect to (e.g., from) a second surface, opposite of the first surface, of the flat portion GC2. When a portion of the metal material layer 151 is etched, portions of the first sacrificial layer structure 165 and the second sacrificial layer structure 167 may also be etched.

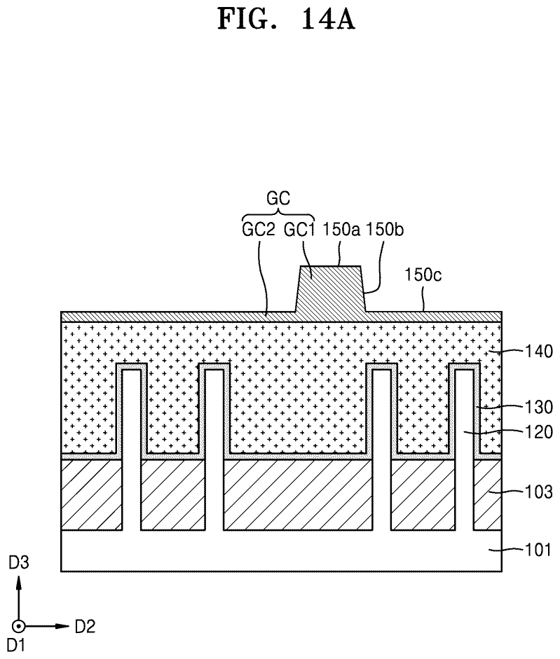

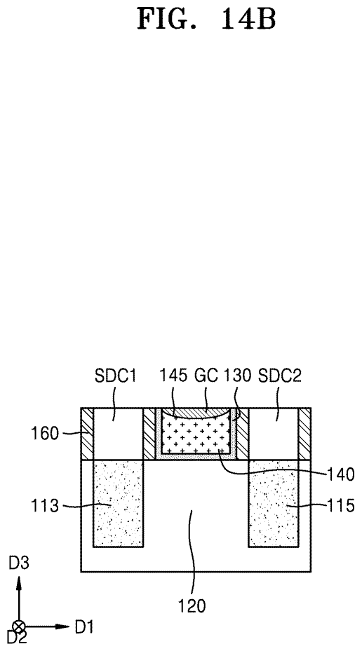

Next, referring to FIGS. 14A and 14B, the first sacrificial layer structure 165 and the second sacrificial layer structure 167 may be etched to expose the first source/drain 113 and the second source/drain 115, and a first source/drain contact structure SDC1 and a second source/drain contact structure SDC2 that contact the first source/drain 113 and the second source/drain 115, respectively, may be formed. For example, the first sacrificial layer structure 165 and the second sacrificial layer structure 167 may be etched, and the etch stop layer 160a may also be etched. The first source/drain contact structure SDC1 and the second source/drain contact structure SDC2 may be formed to contact the exposed first source/drain 113 and the exposed second source/drain 115, respectively.

FIG. 15A is a view for explaining a semiconductor device 200 according to an embodiment, and shows an on-gate-cut cross-sectional view. The semiconductor device 200 according to the embodiment of FIG. 15A is different from the semiconductor device 100 according to the embodiment described above with reference to FIGS. 1 to 3 in that the gate contact structure GC has only a protrusion GC1 and the gate electrode 140 has a protrusion pattern 140a. In FIG. 15A, components that are substantially the same as those in FIGS. 1 to 3 are indicated by the same reference numerals as those in FIGS. 1 to 3, and repetitive descriptions thereof may be omitted.

As illustrated in FIG. 15A, in the semiconductor device 200 according to the embodiment, the gate electrode 140 may have a structure in which the protrusion pattern 140a is formed in some area, and the protrusion GC1 of the gate contact structure GC may be formed to contact on the protrusion pattern 140a of the gate electrode 140. In this case, the protrusion GC1 of the gate contact structure GC may be formed to have a continuous slope on the protrusion pattern 140a of the gate electrode 140.

A method of manufacturing the semiconductor device 200 according to the embodiment of FIG. 15A may use the manufacturing process of FIGS. 4A to 14B. In the process of partially etching the metal material layer 151 for forming the gate contact structure GC of FIGS. 13A and 13B, the flat portion GC2 and a portion of the gate electrode 140 in contact therewith may be etched to form the protrusion pattern 140a, and the gate contact structure GC having only the protrusion GC1 on the protrusion pattern 140a of the gate electrode 140 may be formed. Thereafter, by applying the manufacturing process of FIGS. 14A and 14B, a first source/drain contact structure SDC1 and a second source/drain contact structure SDC2 in contact with the first source/drain 113 and the second source/drain 115, respectively, may be formed.

FIG. 15B is a view for explaining a semiconductor device 300 according to an embodiment, and shows an on-gate-cut cross-sectional view. The semiconductor device 300 according to the embodiment of FIG. 15B is different from the semiconductor device 100 according to the embodiment described above with reference to FIGS. 1 to 3 in that at least a portion of the gate electrode 140 is positioned below the uppermost end of the channel 120 in the third direction D3. In FIG. 15B, components that are substantially the same as those in FIGS. 1 to 3 are indicated by the same reference numerals as those in FIGS. 1 to 3, and repetitive descriptions thereof may be omitted.

As illustrated in FIG. 15B, in the semiconductor device 300 according to the embodiment, a structure, in which at least a portion of the gate electrode 140 is positioned below the uppermost end of the channel 120 in the third direction D3, may be formed, and thus, the flat portion GC2 of the gate contact structure GC may have one side (e.g., one surface 147) having a non-planar shape, which contacts not only the gate electrode 140 but also the gate insulating layer 130, and the protrusion GC1 may protrude in the third direction D3 with respect to (e.g., from) an opposite side (e.g., a surface opposite the one surface 147) of the flat portion GC2.

A method for manufacturing the semiconductor device 300 according to the embodiment of FIG. 15B may use the manufacturing process of FIGS. 4A to 11B. Before the formation of the metal material layer 151 for forming the gate contact structure GC of FIGS. 12A and 12B, a process of etching the gate electrode 140 may be added to form the structure in which at least a portion of the gate electrode 140 is positioned below the uppermost end of the channel 120 in the third direction D3. Thereafter, by applying the manufacturing process of FIGS. 12A to 14B, a gate contact structure GC, which includes a flat portion GC2 whose one surface 147 contacts the gate electrode 140 and a protrusion GC1 that protrudes in the third direction D3 with respect to (e.g., from) an opposite surface of the flat portion GC2, may be formed, and a first source/drain contact structure SDC1 and a second source/drain contact structure SDC2 in contact with the first source/drain 113 and the second source/drain 115, respectively, may be formed.

As another example, a method of manufacturing the semiconductor device 300 according to the embodiment of FIG. 15B may use the manufacturing process of FIGS. 4A to 14B. In a process of selectively and partially etching the organic material layer 170 of FIGS. 7A and 7B to expose at least a portion of the first work function metal layer 141, a portion of the first work function metal layer 141 may be exposed in a region between the channels 120 even in the on-gate-cut cross-sectional view of FIG. 7A. Then, when the manufacturing process of FIGS. 8A to 11B is used, a structure, in which at least a portion of the gate electrode 140 is positioned below the uppermost end of the channel 120 in the third direction D3, may be formed. Thereafter, by applying the manufacturing process of FIGS. 12A to 14B, a gate contact structure GC, which includes a flat portion GC2 whose one surface 147 contacts the gate electrode 140 and a protrusion GC1 that protrudes in the third direction D3 with respect to (e.g., from) an opposite surface of the flat portion GC2, may be formed, and a first source/drain contact structure SDC1 and a second source/drain contact structure SDC2 in contact with the first source/drain 113 and the second source/drain 115, respectively may be formed.

FIGS. 16 to 19 are views for explaining semiconductor devices 400, 500, and 600 according to other embodiments. FIGS. 16 to 18 show on-gate-cut cross-sectional views of the semiconductor devices 400, 500, and 600 according to embodiments, respectively. FIG. 19 shows an on-active-cut cross-sectional view of each of the semiconductor devices 400, 500, and 600 of FIGS. 16 to 18. For convenience of explanation, some components are omitted in FIGS. 16 to 19. FIGS. 16 to 18 show examples in which the semiconductor devices 400, 500, and 600 have gate contact structures GC corresponding to those of the semiconductor devices 100, 200, and 300 illustrated in FIGS. 2, 15A, and 15B, respectively.

Referring to FIGS. 16 to 19, the semiconductor devices 400, 500, and 600 according to the embodiments may each include a GAA channel structure in which channels layers CH, which may be nanosheet-shaped, are stacked in a third direction D3. As shown in FIGS. 16 to 19, the semiconductor devices 400, 500, and 600 may include the channels layers CH, a gate electrode GE, a gate insulating layer GI, a first source/drain SD1, and a second source/drain SD2. However, because materials constituting the corresponding elements may be inferred from the semiconductor devices 100, 200, and 300 according to the embodiments described with reference to FIGS. 1 to 15B, repetitive descriptions thereof may be omitted.

Each of the semiconductor devices 400, 500, and 600 may include a plurality of channel layers CH stacked and arranged in the third direction D3 on a substrate 101, a first source/drain SD1 and a second source/drain SD2 apart from each other in a first direction D1 and in contact with the channel layers CH, and a plurality of gate electrodes GE respectively apart from the plurality of channel layers CH. The gate insulating layer GI may be arranged between the gate electrode GE and the channel layer CH. The gate electrode GE and the channel layer CH may be alternately arranged in the third direction D3, and the gate insulating layer GI may be in a form that surrounds the gate electrode GE. Contacts between each of the channel layers CH and the first source/drain SD1 and between each of the channel layers CH and the second source/drain SD2 may have edge contact forms. For example, two ends of the channel layer CH may be in contact with the first source/drain SD1 and the second source/drain SD2, respectively.

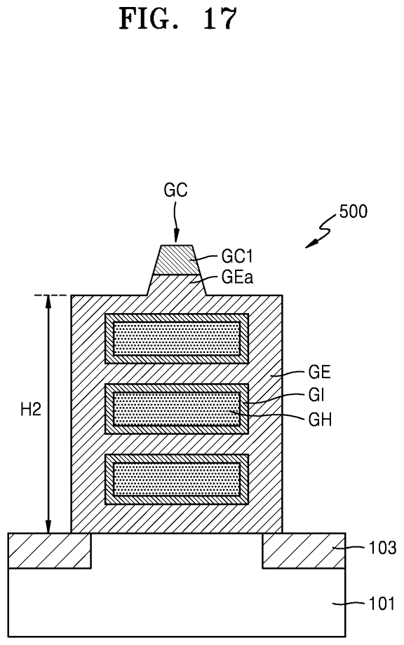

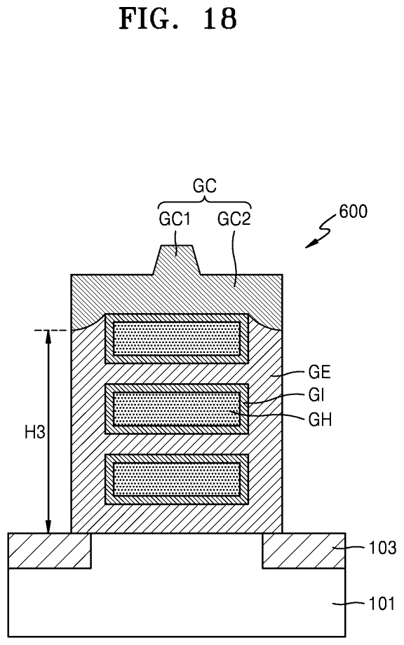

As illustrated in FIG. 16, the semiconductor device 400 may have a structure in which a gate contact structure GC having a protrusion GC1 and a flat portion GC2 is formed in contact with an upper portion of the gate electrode GE, as described above with reference to FIG. 2. As illustrated in FIG. 17, the semiconductor device 500 may have a structure in which a protrusion pattern GEa is formed in the upper end of the gate electrode GE, and a gate contact structure GC is formed to have only a protrusion GC1 formed on the protrusion pattern GEa and in contact with the protrusion pattern GEa, as described above with reference to FIG. 15A. As illustrated in FIG. 18, the semiconductor device 600 may have a structure in which at least a portion of the gate electrode GE is positioned below the uppermost end of the channel CH in the third direction D3, and thus, the flat portion GC2 of the gate contact structure GC has one side having a non-planar shape, which contacts not only the gate electrode GE but also the gate insulating layer GI, and an opposite side, and the protrusion GC1 protrudes in the third direction D3 with respect to (e.g., from) the opposite side, as described above with reference to FIG. 15B.

Considering that the heights from the upper surface of the substrate 101 to the upper end of the gate electrode structure GC in the semiconductor devices 400, 500, and 600 illustrated in FIGS. 16 to 18 are the same, heights H1, H2, and H3 from the upper surface of the substrate 101 to the upper end of the gate electrode GE may be in the order of H1>H2>H3 due to a difference in the gate electrode structure GC.

In addition, as described above, the first source/drain contact structure SDC1 and the second source/drain contact structure SDC2 may be formed in contact on the first source/drain SD1 and the second source/drain SD2 of FIG. 19, respectively. In FIG. 19, the gate contact structure GC, the first source/drain contact structure SDC1, and the second source/drain contact structure SDC2 are omitted for convenience.

Each of the gate electrodes GE of the semiconductor devices 400, 500, and 600 may be arranged to be apart from the first source/drain SD1 and the second source/drain SD2, as illustrated in FIG. 19, and a spacer 105 may be further arranged between the gate electrode GE and the first source/drain SD1 and between the gate electrode GE and the second source/drain SD2. Because the first source/drain SD1, the gate electrode GE, and the second source/drain SD2 are arranged in a first direction D1, a parasitic capacitance may occur between the first source/drain SD1 and the gate electrode GE and between the gate electrode GE and the second source/drain SD2. In order to reduce the parasitic capacitance, the spacer 105 may include, for example, a boron nitride layer. Because the boron nitride layer has no porosity and has mechanical strength, the boron nitride layer may safely support the channel layer CH arranged on the spacer 105. As another example, the spacer 105 may include at least one from among SiCN, SiCON, and SiN. In addition, the spacer 160 may include, for example, a multi-layer including at least two from among SiCN, SiCON, and SiN.

Each of the semiconductor devices 400, 500, and 600 may have a multi-bridge form in which a plurality of channel layers CH each have opposite ends in contact with the first source/drain SD1 and the second source/drain SD2 and are stacked to be apart from each other in a direction away from the substrate 101. Such a multi-bridge form of the channel may reduce a short channel effect and reduce an area occupied by a source/drain, which is advantageous for high integration. In addition, the multi-bridge form may maintain a uniform source/drain junction capacitance regardless of the position of the channel, and thus may be applied to high-speed and high-reliability devices.

In this way, the gate contact structure GC having the protrusion GC1 may be applied to various semiconductor devices, such as a FinFET structure having a fin channel formed by extending in a third direction D3 perpendicular to the substrate 101, or a GAA transistor having a GAA channel.

FIG. 20 is an equivalent circuit diagram of a memory device according to an embodiment.

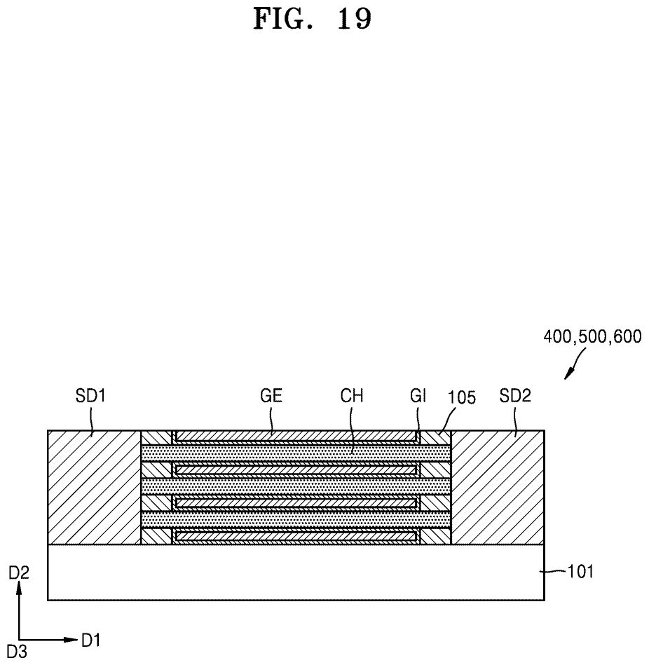

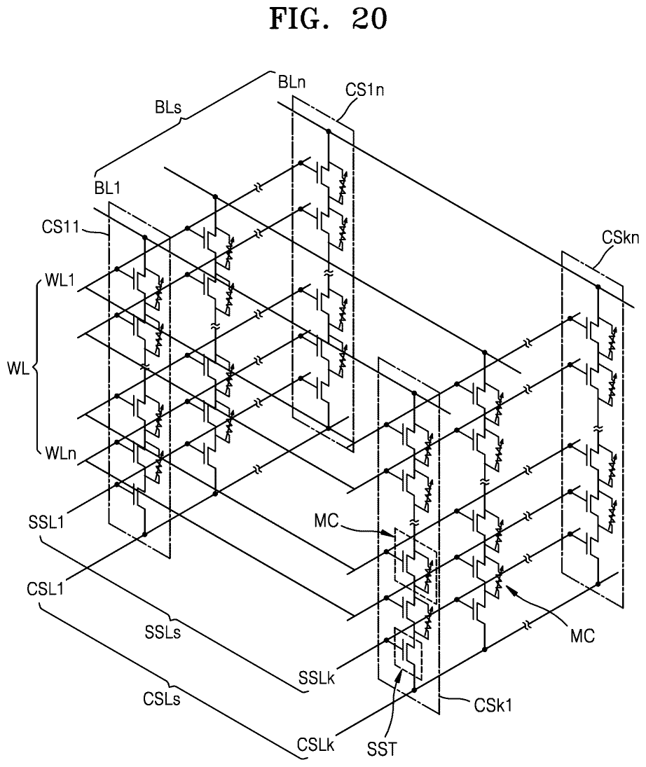

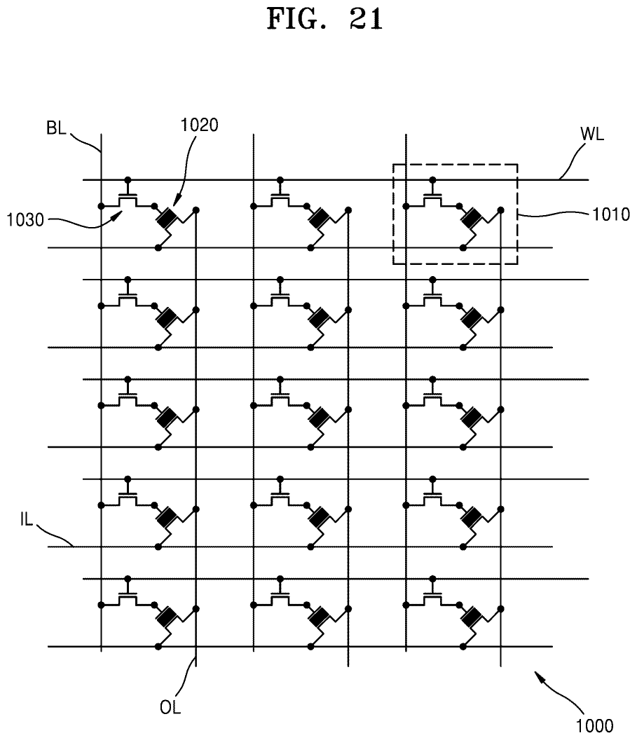

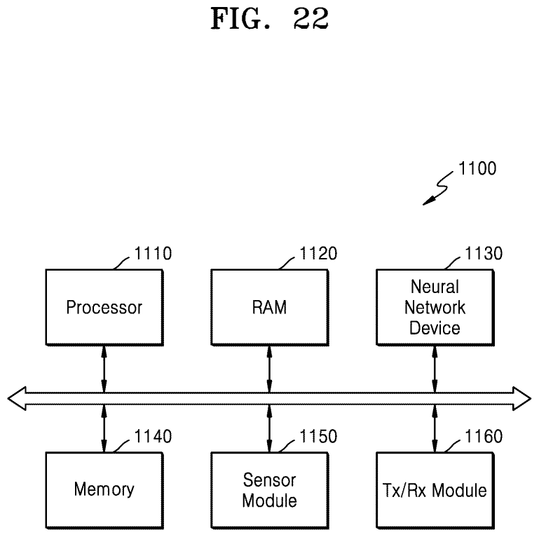

Referring to FIG. 20, the memory device may include a plurality of memory cell strings CS11 to CSkn. The plurality of memory cell strings CS11 to CSkn may be two-dimensionally arranged in a row direction and a column direction to form rows and columns. Each of the memory cell strings CS11 to CSkn may include a plurality of memory cells MC and a plurality of string selection transistors SST. The memory cells MC and string selection transistors SST of each of the memory cell strings CS11 to CSkn may be stacked in a height direction. The memory cells MC in each of the memory cell strings CS11 to CSkn may each correspond to a circuit in which a transistor and a resistor are connected in parallel. For example, each of the memory cell strings CS11 to CSkn may be a memory cell string illustrated in FIGS. 21 and 22.

The rows of the plurality of memory cell strings CS11 to CSkn may be connected to different string selection lines SSL1 to SSLk, respectively. For example, the string selection transistors SST of the memory cell strings CS11 to CS1n may be commonly connected to the string selection line SSL1. The string selection transistors SST of the memory cell strings CSk1 to CSkn may be commonly connected to the string selection line SSLk.

In addition, the columns of the plurality of memory cell strings CS11 to CSkn may be respectively connected to different bit lines BL1 to BLn. For example, the memory cells MC and the string selection transistors SST of the memory cell string CS11 to CSk1 may be commonly connected to the bit line BL1, and the memory cells MC and the string selection transistors SST of the memory cell strings CS1n to CSkn may be commonly connected to the bit line BLn.

In addition, the rows of the plurality of memory cell strings CS11 to CSkn may be respectively connected to different common source lines CSL1 to CSLk. For example, the string selection transistors SST of the memory cell strings CS11 to CS1n may be commonly connected to the common source line CSL1, and the string selection transistors SST of the memory cell strings CSk1 to CSkn may be commonly connected to the common source line CSLk.

Memory cells MC located at the same height from the substrate 101 (or the string selection transistors SST) may be commonly connected to one word line WL, and memory cells MC located at different heights may be connected to different word lines WL1 to WLm, respectively.

In this structure, writing and reading may be performed in units of rows of the memory cell strings CS11 to CSkn. For example, the memory cell strings CS11 to CSkn may be selected in units of rows by common source lines CSLs, and the memory cell strings CS11 to CSkn may be selected in a unit of one row by string selection lines SSLs. In a selected row of the memory cell strings CS11 to CSkn, writing and reading may be performed in a unit of a page. For example, a page may be one row of memory cells MC connected to one word line WL. In a selected row of the memory cell strings CS11 to CSkn, memory cells MC may be selected in a unit of a page by word lines WL.

FIG. 21 is a schematic circuit diagram of a neural network device 1000 according to an embodiment. Referring to FIG. 21, the neural network device 1000 according to an embodiment may include an array of a plurality of synaptic elements 1010 arranged in a two-dimensional manner. Each of the plurality of synaptic elements 1010 may include an access transistor 1030 and a field effect transistor 1020. The field effect transistor 1020 may be any one of the semiconductor devices 100, 200, 300, 400, 500, and 600 described with reference to FIGS. 1 to 19 or a semiconductor device that is a combination or modification thereof. The access transistor 1030 may function as a selection element that turns the synaptic element 1010 on/off.

The neural network device 1000 may also include a plurality of word lines WL, a plurality of bit lines BL, a plurality of input lines IL, and a plurality of output lines OL. The gate of the access transistor 1030 may be electrically connected to one of the word lines WL, the source of the access transistor 1030 may be electrically connected to one of the bit lines BL, and the drain of the access transistor 1030 may be electrically connected to the gate of the field effect transistor 1020. In addition, the source of the field effect transistor 1020 may be electrically connected to one of the input lines IL, and the drain of the field effect transistor 1020 may be electrically connected to one of the output lines OL.

During a learning operation of the neural network device 1000, the access transistor 1030 may be individually turned on through an individual word line WL, and a program pulse may be applied to the gate of the field effect transistor 1020 through a bit line BL. A signal of learning data may be applied through an input line IL. Through this process, weight may be stored in each field effect transistor 1020.

During an inference operation of the neural network device 1000, all access transistors 1030 may be turned on through all word lines WL, and a read voltage may be applied through the bit line BL. Thus, currents from synaptic elements 1010 connected in parallel to each output line OL may be added together and flow to each output line OL. An output circuit may be connected to the plurality of output lines OL, so that the current flowing through each output line OL may be converted into a digital signal.

FIG. 22 is a schematic block diagram illustrating an example configuration of an electronic apparatus 1100 including a neural network device. Referring to FIG. 22, the electronic apparatus 1100 may analyze input data in real time based on a neural network to extract valid information, determine a situation based on the extracted information, or control configurations of a device equipped with the electronic apparatus 1100. For example, the electronic apparatus 1100 may be applied to a robot device such as a drone, an advanced driver assistance system (ADAS), or the like, a smart television (TV), a smartphone, a medical device, a mobile device, an image display device, a measurement device, and an Internet of Things (IoT) device, and the like, and may also be mounted on at least one of various types of devices.

The electronic apparatus 1100 may include a processor 1110, a random access memory (RAM) 1120, a neural network device 1130, a memory 1140, a sensor module 1150, and a communication (Tx/Rx) module 1160. The electronic apparatus 1100 may further include an input/output module, a security module, a power control device, and the like. Some of the hardware components of the electronic apparatus 1100 may be mounted on at least one semiconductor chip.

The processor 1110 may control the overall operation of the electronic apparatus 1100. The processor 1110 may include one processor core (i.e., Single-Core) or a plurality of processor cores (i.e., Multi-Core). The processor 1110 may process or execute programs and/or data stored in the memory 1140. In some embodiments, the processor 1110 may control the function of the neural network device 1130 by executing programs stored in the memory 1140. The processor 1110 may be implemented as a central processing unit (CPU), a graphics processing unit (GPU), an application processor (AP), or the like.

The RAM 1120 may temporarily store programs, data, or instructions. For example, programs and/or data stored in the memory 1140 may be temporarily stored in the RAM 1120 according to the control or boot code of the processor 1110. The RAM 1120 may be implemented as a memory such as dynamic RAM (DRAM), static RAM (SRAM), or the like.

The neural network device 1130 may perform an operation of the neural network based on the received input data and generate an information signal based on the execution result. The neural network may include, but is not limited to, a convolutional neural network (CNN), a recurrent neural network (RNN), a feedfowrad neural network (FNN), long short-term memory (LSTM), stacked neural network (SNN), state-space dynamic neural network (SSDNN), deep belief networks (DBN), restricted Boltzmann machine (RBM), or the like. The neural network device 1130 may be a hardware accelerator itself dedicated to a neural network or an apparatus including the same. The neural network device 1130 may perform a read or write operation as well as an operation of the neural network.

The information signal may include one of various types of recognition signals such as a voice recognition signal, an object recognition signal, an image recognition signal, a biometric information recognition signal, and the like. For example, the neural network device 1130 may receive frame data included in the video stream as input data and generate, from frame data, a recognition signal for an object included in an image represented by the frame data. However, the neural network device 1130 is not limited thereto, and the neural network device 1130 may receive various types of input data and generate a recognition signal according to the input data, according to the type or function of the device on which the electronic apparatus 1100 is mounted.

The neural network device 1130 may perform, for example, machine learning model such as linear regression, logistic regression, statistical clustering, Bayesian classification, decision trees, principal component analysis, and/or expert system, and/or machine learning model of ensemble techniques, etc., such as random forest. The machine learning model may be used to provide various services such as, for example, image classification service, user authentication service based on biometric information or biometric data, advanced driver assistance system (ADAS), voice assistant service, automatic speech recognition (ASR) service, and the like.

The memory 1140 is a storage place for storing data and may store an operating system (OS), various programs, and various pieces of data. In an embodiment, the memory 1140 may store intermediate results generated during the operation of the neural network device 1130.

The memory 1140 may be a DRAM, but is not limited thereto. The memory 1140 may include at least one from among a volatile memory and a nonvolatile memory. The nonvolatile memory includes read-only memory (ROM), programmable ROM (PROM), electrically programmable ROM (EPROM), electrically erasable and programmable ROM (EEPROM), flash memory, phase-change RAM (PRAM), magnetic RAM (MRAM), resistive RAM (RRAM), ferroelectric RAM (FRAM), and the like. The volatile memory includes dynamic RAM (DRAM), static RAM (SRAM), synchronous DRAM (SDRAM), phase-change RAM (PRAM), magnetic RAM (MRAM), resistive RAM (RRAM), and ferroelectric RAM (FeRAM). In an embodiment, the memory 1140 may include at least one from among a hard disk drive (HDD), a solid-state drive (SSD), a compact flash (CF), a secure digital (SD), a micro secure digital (Micro-SD), a mini secure digital (Mini-SD), and a memory stick.

The sensor module 1150 may collect information around a device on which the electronic apparatus (e.g., the semiconductor device 200) is mounted. The sensor module 1150 may sense or receive a signal (e.g., an image signal, a voice signal, a magnetic signal, a bio signal, a touch signal, etc.) from the outside of the electronic apparatus 1100 and convert the sensed or received signal into data. To this end, the sensor module 1150 may include at least one of various types of sensing devices such as a sensing device such as, for example, a microphone, an imaging device, an image sensor, a light detection and ranging (LIDAR) sensor, an ultrasonic sensor, an infrared sensor, a biosensor, and a touch sensor.

The sensor module 1150 may provide the converted data to the neural network device 230 as input data. For example, the sensor module 1150 may include an image sensor, generate a video stream by photographing an external environment of the electronic apparatus 1100, and sequentially provide the continuous data frame of the video stream to the neural network device 1130 as input data. However, embodiments are not limited thereto, and the sensor module 1150 may provide various types of data to the neural network device 1130.

The communication module 1160 may include various wired or wireless interfaces capable of communicating with an external device. For example, the communication module 1160 may include a wired local area network (LAN), a wireless local area network (WLAN) such as a wireless fidelity (Wi-Fi), a wireless personal area network (WPAN) such as Bluetooth, a wireless universal serial bus (USB), Zigbee, near field communication (NFC), radio-frequency identification (RFID), power line communication (PLC), or a communication interface capable of connecting to a mobile cellular network, such as 3rd generation (3G), 4th generation (4G), long term evolution (LTE), or the like.

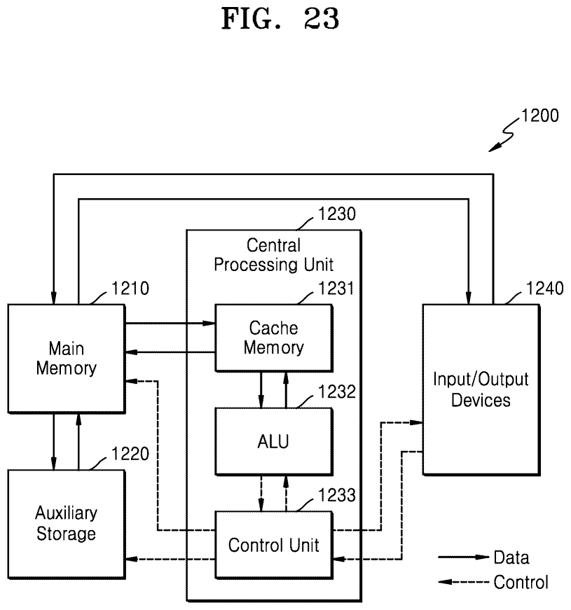

The semiconductor devices 100, 200, 300, 400, 500, and 600 according to the embodiments may be used for data storage in various electronic apparatuses. FIG. 23 is a schematic conceptual diagram showing a device architecture that may be applied to an electronic apparatus 1200 according to an embodiment. Referring to FIG. 23, the electronic apparatus 1200 may include a main memory 1210, an auxiliary storage 1220, a CPU 1230, and an input/output device 1240. The CPU 1230 may include a cache memory 1231, an arithmetic logic unit (ALU) 1232, and a control unit 1233. The cache memory 1231 may include an SRAM. The main memory 1210 may include a DRAM device, and the auxiliary storage 1220 may include at least one from among the semiconductor devices 100, 200, 300, 400, 500, and 600 according to the embodiments. Alternatively, the cache memory 1231, the main memory 1210, and the auxiliary storage 1220 may all include at least one from among the semiconductor devices 100, 200, 300, 400, 500, and 600 according to the embodiments. In some cases, the electronic apparatus 1200 may be implemented in a form in which computing unit devices and memory unit devices are adjacent to each other in one chip, without distinction of the above-described sub-units.

Some of the elements and/or functional blocks disclosed above may be implemented as a processing circuitry such as hardware including a logic circuit; a hardware/software combination such as processor execution software; or a combination thereof. For example, the processing circuitry may include a CPU, an ALU, a digital signal processor, a microcomputer, a field programmable gate array (FPGA), a system-on-chip (SoC), a programmable logic unit, a microprocessor, an application-specific integrated circuit (ASIC), and/or the like. The processing circuitry may include electronic components such as at least one from among a transistor, a resistor, a capacitor, and the like. The processing circuitry may include electronic components such as at least one logic gate of an AND gate, an OR gate, a NAND gate, a NOR gate, and the like.

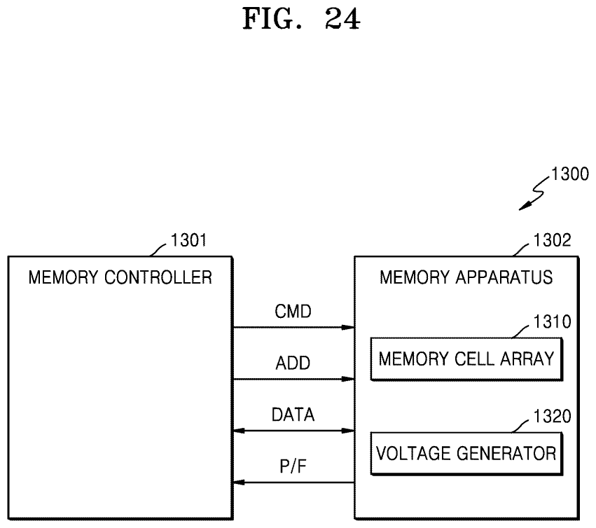

FIG. 24 is a block diagram of a memory system 1300 according to an embodiment.

Referring to FIG. 24, the memory system 1300 may include a memory controller 1301 and a memory device 1302. The memory controller 1301 may perform a control operation for the memory device 1302. For example, the memory controller 1301 may provide the memory device 1302 with an address ADD and a command CMD for performing a programming (or writing), reading, and/or erasing operation for the memory device 1302. In addition, data for the programming operation and reading data may be transmitted between the memory controller 1301 and the memory device 1302.

The memory device 1302 may include a memory cell array 1310 and a voltage generator 1320. The memory cell array 1310 may include a plurality of memory cells and may include at least one from among the semiconductor devices 100, 200, 300, 400, 500, and 600 according to the embodiments described above.

The memory controller 1301 may include a processing circuitry such as hardware including a logic circuit; a hardware/software combination such as processor execution software; or a combination thereof. For example, the processing circuitry may be more specifically a CPU, an ALU, a digital signal processor, a microcomputer, an FPGA, an SoC, a programmable logic unit, a microprocessor, an ASIC, or the like, but is not limited thereto. The memory controller 1301 may be configured to operate in response to a request from a host, access the memory device 1302, and control operations (e.g., write/read operations) described above, thereby transforming the memory controller 1301 into a special purpose controller. The memory controller 1301 may generate addresses ADD and commands CMD for performing programming/reading/erase operations on the memory cell array 1310. In addition, in response to a command from the memory controller 1301, the voltage generator 1320 (e.g., a power circuit) may generate a voltage control signal for controlling the voltage level of a word line to program data to or read data from the memory cell array 1310.

In addition, the memory controller 1301 may perform a decision operation on data read from the memory device 1302. For example, the number of on-cells and/or the number of off-cells may be determined from data read from memory cells. The memory device 1302 may provide a pass/fail signal P/F to the memory controller 1301 based on a read result for the read data. The memory controller 1301 may control the write and read operations of the memory cell array 410 by referring to the pass/fail signal P/F.

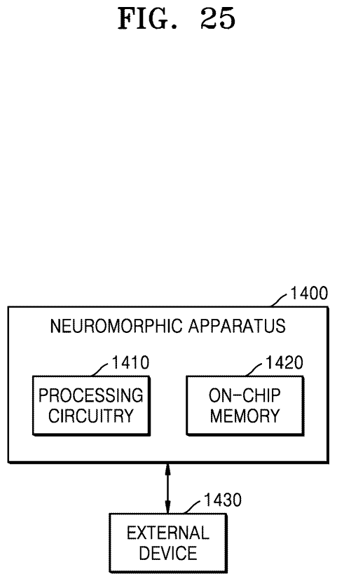

FIG. 25 is a block diagram showing a neuromorphic apparatus 1400 and an external device 1430 connected thereto, according to an embodiment.

Referring to FIG. 25, the neuromorphic apparatus 1400 may include a processing circuitry 1410 and/or an on-chip memory 1420. The on-chip memory 1420 may include at least one from among the semiconductor devices 100, 200, 300, 400, 500, and 600) according to the embodiments described above.

In some embodiments, the processing circuitry 1410 may be configured to control a function for driving the neuromorphic apparatus 1400. For example, the processing circuitry 1410 may be configured to control the neuromorphic apparatus 1400 by executing a program stored in the on-chip memory 1420. In some embodiments, the processing circuitry 1410 may include hardware such as a logic circuit, a hardware/software combination such as a processor executing software, or a combination thereof. For example, the processor may include a CPU, a GPU, an AP included in the neuromorphic apparatus 1400, an ALU, a digital signal processor, a microcomputer, an FPGA, an SoC, a programmable logic unit, a microprocessor, an ASIC, and/or the like, but is not limited thereto. In some embodiments, the processing circuitry 1410 may be configured to read/write various data from/to the external device 1430 and/or execute the neuromorphic apparatus 1400 by using the read/written data. In some embodiments, the external device 1430 may include an external memory having an image sensor (e.g., a CMOS image sensor circuit) and/or a sensor array.

In some embodiments, the neuromorphic apparatus 1400 may be applied to a machine learning system. The machine learning system may utilize various artificial neural network organization and processing models, such as a convolutional neural network (CNN), a deconvolutional neural network, a recurrent neural network (RNN) optionally including a long short-term memory (LSTM) unit and/or a gated recurrent unit (GRU), a stacked neural network (SNN), a state-space dynamic neural network (SSDNN), a deep faith network (DBN), a generative adversarial network (GAN), and/or a restricted Boltzmann machine (RBM).

Alternatively or additionally, the machine learning system may include other forms of machine learning models, such as linear and/or logistic regression, statistical clustering, Bayesian classification, decision trees, dimensionality reduction such as principal component analysis, expert systems, and/or combinations thereof, including ensembles such as random forests. The machine learning model may be used to provide various services and/or applications, such as image classification service, user authentication service based on biometric information or biometric data, advanced driver assistance system (ADAS) service, voice assistant service, and automatic speech recognition (ASR) service, which may be executed by electronic apparatuses.

According to a semiconductor device and a method of manufacturing the same, according to embodiments, a gate contact structure formed of a second metal material having lower resistance than a first metal material is provided to have, on a gate electrode including the first metal material, a protrusion that protrudes beyond the uppermost end of the gate electrode, thereby reducing contact resistance.

It should be understood that embodiments described herein should be considered in a descriptive sense only and not for purposes of limitation. Descriptions of features or aspects within each embodiment the present disclosure should typically be considered as available for other similar features or aspects in other embodiments of the present disclosure. While one or more embodiments have been described with reference to the figures, it will be understood by those of ordinary skill in the art that various changes in form and details may be made therein without departing from the spirit and scope of the present disclosure.

What is claimed is:

1. A semiconductor device comprising:
a channel on a substrate;
a first source/drain;
a second source/drain spaced apart from the first source/drain in a first direction, wherein the channel is between the first source/drain and the second source/drain in the first direction;
a gate insulating layer surrounding the channel;
a gate electrode surrounding the channel, wherein the gate insulating layer is between the gate electrode and the channel, and the gate electrode comprises a first metal material; and
a gate contact structure contacting the gate electrode, the gate contract structure comprising a second metal material having a lower electrical resistance than an electrical resistance of the first metal material, and
wherein the gate contact structure comprises a protrusion that protrudes beyond an uppermost end of the gate electrode in a third direction crossing the first direction.

2. The semiconductor device of claim 1, wherein the gate contact structure further comprises a flat portion, wherein a first surface of the flat portion contacts the gate electrode, and
wherein the protrusion protrudes in the third direction from a second surface of the flat portion, opposite of the first surface.

3. The semiconductor device of claim 1, wherein at least a portion of the gate electrode is below an uppermost end of the channel in the third direction,
wherein a first surface of the gate contact structure contacts the gate electrode and the gate insulating layer, and
wherein the protrusion protrudes in the third direction from a second surface of the gate contact structure, opposite of the first surface.

4. The semiconductor device of claim 1, wherein a portion of the gate electrode comprises a protrusion pattern, and the protrusion of the gate contact structure is on the protrusion pattern of the gate electrode.

5. The semiconductor device of claim 4, wherein the protrusion of the gate contact structure has a continuous slope on the protrusion pattern of the gate electrode.

6. The semiconductor device of claim 1, wherein the second metal material comprises at least one from among tungsten and cobalt.

7. The semiconductor device of claim 1, wherein the channel comprises a fin channel or a gate all around channel.

8. A method of manufacturing a semiconductor device, the method comprising:
forming a channel on a substrate;
forming a first source/drain at a first end of the channel and a second source/drain at a second end of the channel, wherein the first source/drain and the second source/drain are apart from each other in a first direction;
forming a first sacrificial layer structure and a second sacrificial layer structure on the first source/drain and the second source/drain, respectively, wherein each of the first sacrificial layer structure and the second sacrificial layer structure has a first height in a third direction that crosses the first direction;
forming a gate insulating layer on the channel;
forming a first work function metal layer by using a first metal material on the gate insulating layer such that the first work function metal layer is not folded between the first sacrificial layer structure and the second sacrificial layer structure;
forming an organic material layer by applying an organic material on the first work function metal layer;
exposing a portion of the first work function metal layer between the first sacrificial layer structure and the second sacrificial layer structure by selectively and partially etching the organic material layer;
forming a primary gate electrode structure on the gate insulating layer between the first sacrificial layer structure and the second sacrificial layer structure by etching an exposed portion of the first work function metal layer and removing the organic material layer, the primary gate electrode structure including a bottom portion and two sidewall portion structures, wherein the two sidewall portion structures are spaced apart from each other;
folding the primary gate electrode structure between the first sacrificial layer structure and the second sacrificial layer structure by forming a second work function metal layer by using a third metal material on the primary gate electrode structure;
obtaining a gate electrode, which includes a folding portion of the primary gate electrode structure, by partially etching the second work function metal layer; and
forming a gate contact structure that contacts the gate electrode, the gate contact structure including a second metal material having lower electrical resistance than an electrical resistance of each of the first metal material and the third metal material, the gate contact structure including a protrusion protruding beyond an uppermost end of the gate electrode.

9. The method of claim 8, wherein the first metal material and the third metal material comprise a same metal material as each other.

10. The method of claim 8, wherein the forming the gate contact structure comprises:
forming a metal material layer comprising the second metal material on the gate electrode; and
forming the gate contact structure by etching a portion of the metal material layer.

11. The method of claim 10, wherein the forming the gate contract structure comprises etching portions of the first sacrificial layer structure and the second sacrificial layer structure together with the metal material layer.

12. The method of claim 10, further comprising:
exposing the first source/drain and the second source/drain by etching the first sacrificial layer structure and the second sacrificial layer structure to ; and
forming a first source/drain contact structure and a second source/drain contact structure that contact the first source/drain and the second source/drain, respectively.

13. The method of claim 8, wherein the gate contact structure includes a flat portion, wherein a first surface of the flat portion contacts the gate electrode, and the protrusion protrudes in the third direction from a second surface of the flat portion, opposite of the first surface.

14. The method of claim 8, wherein at least a portion of the gate electrode is below an uppermost end of the channel in the third direction,
wherein a first surface of the gate contact structure contacts the gate electrode and the gate insulating layer, and
wherein the protrusion protrudes in the third direction from a second surface of the gate contact structure, opposite of the first surface.

15. The method of claim 8, wherein a portion of the gate electrode includes a protrusion pattern, and the protrusion of the gate contact structure is on the protrusion pattern of the gate electrode.

16. The method of claim 15, wherein the protrusion of the gate contact structure has a continuous slope on the protrusion pattern of the gate electrode.

17. The method of claim 8, wherein the second metal material comprises at least one from among tungsten and cobalt.

18. The method of claim 8, wherein the channel comprises a fin channel or a gate all around channel.

19. An electronic apparatus comprising:
a substrate; and
a plurality of memory cells repeatedly arranged in a first direction and a second direction on the substrate, the second direction crossing the first direction,
wherein each of the plurality of memory cells comprises:
a channel on the substrate;
a first source/drain;
a second source/drain spaced apart from the first source/drain in the first direction, wherein the channel is between the first source/drain and the second source/drain in the first direction;
a gate insulating layer surrounding the channel;
a gate electrode surrounding the channel, wherein the gate insulating layer is between the gate electrode and the channel, and the gate electrode comprises a first metal material; and
a gate contact structure contacting the gate electrode, the gate contract structure comprising a second metal material having a lower electrical resistance than an electrical resistance of the first metal material, and
wherein the gate contact structure comprises a protrusion that protrudes beyond an uppermost end of the gate electrode in a third direction crossing the first direction and the second direction.

20. The electronic apparatus of claim 19, wherein the channel comprises a fin channel or a gate all around channel.
